(19) United States
(12) Patent Application Publication
(10) Pub. No.: US 2007/0281082 A1
(43) Pub. Date: Dec. 6, 2007

(54) Flash Heating in Atomic Layer Deposition

(76) Inventors: Nima Mokhlesi, Los Gatos, CA (US); Randhir Thakur, San Jose, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/421,992

(22) Filed: Jun. 2, 2006

(51) Int. Cl. C23C 16/00; B05D 3/00; B29C 71/04; B29C 71/02

(52) U.S. Cl. 427/248.1; 427/532; 264/482

(57) ABSTRACT

System and methods for flash heating of materials deposited using atomic layer deposition techniques are disclosed. By flash heating the surface of the deposited material after each or every few deposition cycles, contaminants such as un-reacted precursors and byproducts can be released from the deposited material. A higher quality material is deposited by reducing the incorporation of impurities. A flash heating source is capable of quickly raising the temperature of the surface of a deposited material without substantially raising the temperature of the bulk of the substrate on which the material is being deposited. Because the temperature of the bulk of the substrate is not significantly raised, the bulk acts like a heat sink to aid in cooling the surface after flash heating. In this manner, processing times are not significantly increased in order to allow the surface temperature to reach a suitably low temperature for deposition.

### CROSS-REFERENCE TO RELATED APPLICATIONS

The following applications are cross-referenced and incorporated by reference herein in their entirety:

U.S. patent application Ser. No. ______, filed concurrently, entitled “Atomic Layer Deposition of Oxides Using Krypton as an Ion Generating Feed Gas,” by Mokhlesi et al., filed concurrently (Attorney Docket No. SAND-01025US0); and

U.S. patent application Ser. No. ______, filed concurrently, entitled “Systems for Atomic Layer Deposition of Oxides Using Krypton as an Ion Generating Feed Gas,” by Mokhlesi et al., filed concurrently (Attorney Docket No. SAND-01025US1);

U.S. patent application Ser. No. ______, filed concurrently, entitled “Systems for Flash Heating in Atomic Layer Deposition,” by Mokhlesi et al., filed concurrently (Attorney Docket No. SAND-01026US1).

### BACKGROUND OF THE INVENTION

1. Field of the Invention

The present invention relates generally to technology for atomic layer deposition.

2. Description of the Related Art

Atomic layer deposition (ALD) is characterized by self-limiting surface chemical reactions resulting from the alternate exposure of a substrate surface to precursors. Between exposures, the ALD chamber (reactor) is purged to remove any excess precursor. Thus, the precursors (typically gases or liquids and sometimes solids) do not mix in the gas phase such that reactions are limited to the substrate surface. The first precursor gas is pulsed or otherwise introduced onto the substrate surface causing chemisorption or surface reactions to take place at the substrate surface. After purging the chamber of any excess materials left from the first precursor, the second precursor is introduced to the substrate surface, reacting with the adsorbed fist precursor to form a monolayer of the desired film. The chamber is purged again to remove any un-reacted materials or byproducts. The process is repeated until a desired film thickness is reached. Because ALD is based on saturated surface reactions between substrates and precursors, the growth is dependent upon the number of reaction cycles instead of reactant concentrations or growth times, as characterized by other deposition techniques. This results in highly conformal films that can be grown with accurate thicknesses over large areas.

Another characteristic of ALD is low process or deposition temperature compared with other deposition techniques. This characteristic has increased interest in ALD as the need for highly scaled semiconductor fabrication increases. A low process temperature not only leads to a constant monolayer of adsorbed precursor on the substrate, a low temperature minimizes the diffusion of dopants, thus maintaining dopant density profiles in the as-implanted state. A low thermal budget also inhibits the poly-crystallization of high dielectric constant films, reduces the growth rate of and hence the thickness of lower dielectric interfacial layers between high dielectric constant layers and silicon or poly-silicon, and eliminates the inter-diffusion of silicon atoms into high dielectric constant layers and metal atoms into silicon or poly-silicon.

Lower temperatures, however, can also lead to poorer quality of deposited films because of the incorporation of impurities (e.g., those left over from the incomplete reaction of precursors) into the film. If the process temperature is not accurately selected or maintained, surface reactions may not go to completion, leaving un-reacted precursor and/or byproducts on and in the deposited film. Other factors may also lead to the contaminant introduction into a deposited film.

Typical annealing techniques to reduce impurity incorporation in films involve the heating of the bulk of the substrate and may not be suitable for industrial ALD applications. In a low-temperature ALD process, raising the bulk temperature can introduce a delay into the ALD process while waiting for the substrate to cool back to the ALD processing temperature after annealing. If the process is continued at a high temperature, gas-phase precursor reactions, agglomeration, and other negative effects can occur.

Accordingly, there is a need for a mechanism to reduce the incorporation of impurities into films deposited by atomic layer deposition.

### SUMMARY OF THE INVENTION

In accordance with one embodiment, the surface of a deposited material (and/or the substrate on which it is being deposited) is flash heated after each or every few oxidation cycles to reduce the incorporation of impurities such as un-reacted precursors and byproducts into the deposited material. A higher quality material is deposited by reducing the incorporation of impurities through the use of a flash heating source. A flash heating source is capable of quickly raising the temperature of the surface of a deposited material without substantially raising the temperature of the bulk of the substrate on which the material is being deposited. Because the temperature of the bulk of the substrate is not significantly raised, the bulk acts like a heat sink to aid in cooling the surface after flash heating. In this manner, processing times are not significantly increased in order to allow the surface temperature to reach a suitably low temperature for deposition. In one embodiment, the flash heating source is one or more flash lamps. In another embodiment, the flash heating source is one or more lasers.

In one embodiment, a method of depositing a film is provided that comprises: depositing one or more layers of the film onto a substrate during a number of deposition cycles, wherein each of the deposition cycles includes introducing a first precursor to the substrate to adsorb a layer of the first precursor on a surface of the substrate; introducing a second precursor to the substrate to deposit the film; and flash heating the substrate surface after a predetermined number of the deposition cycles to release contaminants from the substrate, wherein flash heating includes raising a temperature of the substrate surface without substantially raising a temperature of a bulk of the substrate.

One embodiment includes an atomic layer deposition system, comprising: at least one chamber adapted to house a substrate upon which a film is to be deposited in a number of atomic layer deposition cycles; and a flash heating source that flash heats a surface of the substrate after each of the deposition cycles. In one embodiment, the at least one chamber includes an upper surface formed of quartz. The flash heating source is disposed above the quartz upper surface to enable energy to pass from the source into the chamber while keeping the chamber sealed.

In one embodiment, a flash heating source is a laser tuned to a specific wavelength based on the characteristics of the material being heated such as its absorption coefficient. In one embodiment, a laser is tuned to more than one wavelength. The laser can be alternately powered at each wavelength or modulated as it heats portions of the substrate surface. In one embodiment, multiple lasers are used that are disposed at differing angles with respect to the substrate surface and the upper surface of a quartz deposition chamber. When using multiple lasers, different ones can be tuned to different wavelengths to efficiently heat different materials.

Another embodiment includes a non-volatile storage device, comprising: source/drain regions; a channel region between the source/drain regions; a floating gate; a control gate; a first dielectric region between the channel region and the floating gate, wherein the first dielectric material includes a high-K material deposited in one or more cycles of an atomic layer deposition process, wherein the high-K material is flash heated after a predetermined number of cycles to release contaminants; and a second dielectric region between the floating gate and the control gate, wherein charge is transferred between the floating gate and the control gate via the second dielectric region.

Other features, aspects, and objects of the invention can be obtained from a review of the specification, the figures, and the claims.

### BRIEF DESCRIPTION OF THE DRAWINGS

FIG. 1 depicts an exemplary ALD process.

FIG. 2 is a generalized block diagram of a deposition system in accordance with one embodiment.

FIG. 3 is a cross-sectional view of a valve system in accordance with one embodiment for delivering precursors to a deposition chamber.

FIG. 4 is a cross-sectional view of a valve system in accordance with another embodiment for delivering precursors to a deposition chamber.

FIG. 5 is cross-sectional view of a valve system in accordance with another embodiment for delivering precursors to a deposition chamber.

FIG. 6 is a block diagram of a pair of valves in accordance with one embodiment for delivering a first precursor and a second precursor to a deposition chamber.

FIG. 7 is top view of a deposition chamber in accordance with one embodiment depicting a substrate platen and individual circular valve rings for evacuating first and second precursors, respectively, in an ALD process.

FIG. 8 is a block diagram of a deposition chamber in accordance with one embodiment including separate exhaust systems for each precursor, substrate absorption plates, and particle filters.

FIG. 9 is an energy diagram illustrating various dissociation energies of oxygen and metastable states of various inert gases.

FIGS. 10A-10B are flowcharts for atomic layer deposition in accordance with one embodiment using plasma generated radicals as a second precursor.

FIG. 11 is a generalized block diagram of a deposition system in accordance with one embodiment.

FIG. 12 is a generalized block diagram of a deposition system in accordance with one embodiment.

FIG. 13 is a generalized block diagram of a deposition system in accordance with one embodiment.

FIG. 14 is a generalized block diagram of a deposition system in accordance with one embodiment.

FIGS. 15A-15D are diagrams depicting the characteristics of flash heating in accordance with embodiments of the present disclosure and those of prior art techniques.

FIG. 16 is a generalized block diagram of a deposition system in accordance with one embodiment.

FIG. 17 is a flowchart depicting a method in accordance with one embodiment for flash heating a deposited material during a deposition process.

FIG. 18 is a top view of a deposition system in accordance with one embodiment.

FIG. 19 is a top view of a deposition system in accordance with one embodiment.

FIG. 20 is a top view of a deposition system in accordance with one embodiment.

FIG. 21 is a generalized block diagram of a deposition system in accordance with one embodiment.

FIG. 22 is a generalized block diagram of a deposition system in accordance with one embodiment.

FIG. 23 is a two-dimensional block diagram of one embodiment of a flash memory cell.

FIG. 24 is a three-dimensional drawing of a pair of four word line long portions of two NAND strings according to one embodiment.

FIG. 25 is a flowchart describing one embodiment of the front end of a process for manufacturing the memory cell of FIG. 23.

FIGS. 26A-26F depict the non-volatile memory device of FIG. 23 at various stages of the process described in FIG. 25.

### DETAILED DESCRIPTION

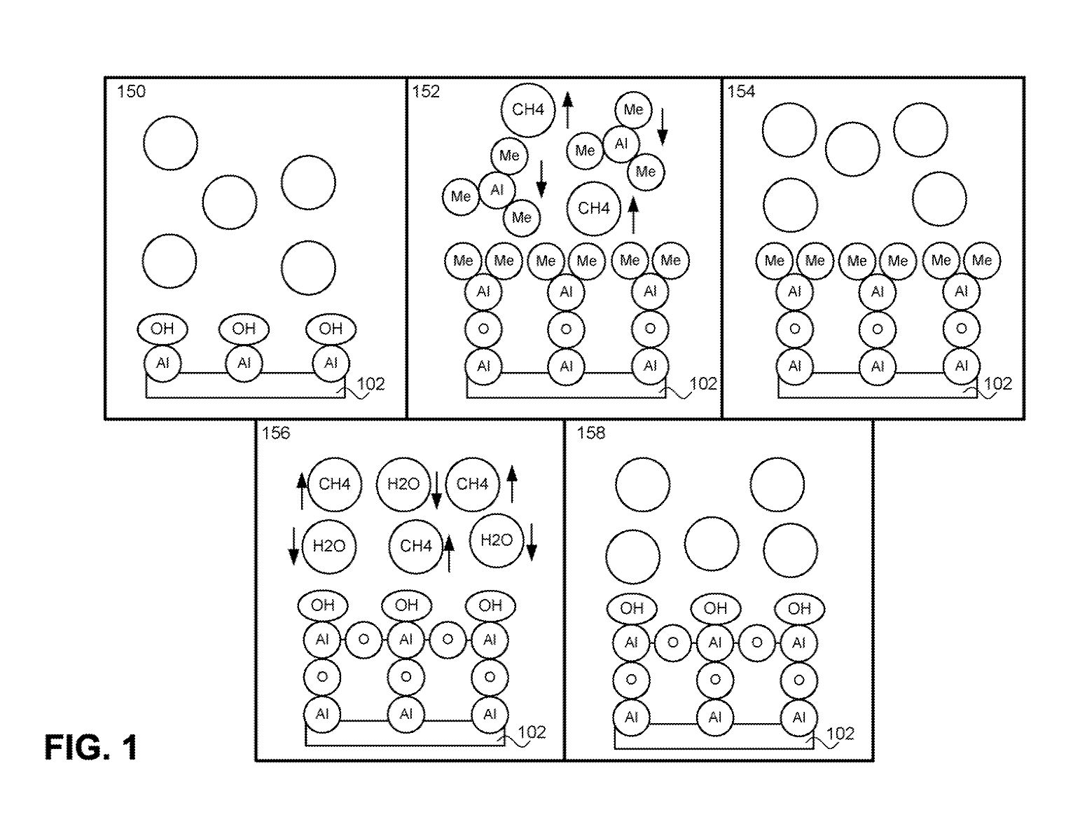

FIG. 1 depicts a simple ALD process for the deposition of an exemplary Al₂O₃ film. Substrate 102 has been hydroxylated, resulting in the chemisorption of OH groups on the surface of the substrate. Step 150 depicts a starting surface having OH groups and an inert gas flow. At step 152 of the ALD process, trimethyl aluminum (TMA=Al(CH₃)₃) is pulsed into the deposition chamber, saturating substrate 102. The TMA is chemisorbed onto the substrate surface, resulting in the deposition of an aluminum containing monolayer (or less) having methyl ligands at the surface. CH₄ is liberated during the first step. The deposition chamber is then purged, step 154, to remove any residual precursor or by-products from the chamber. Various means can be employed to purge the chamber, such as by introducing an inert gas into the chamber at inlet port(s) while pumping out the chamber gas through outlet port(s) that are placed downstream of the gas flow. In one embodiment, nitrogen or argon is used as a purge gas. Although not shown, the first purge step may not be completely effectual. Residual precursor (TMA) and/or by-products such as C or H may remain in the chamber and the substrate surface. The residual precursor and/or by-products can be a result of incomplete surface reaction due to such factors as a low-deposition temperature.

At step 156, water (H₂O) is pulsed into the deposition chamber. The H₂O reacts with the methyl ligands to form OH groups at the surface. CH₄ is generated as a byproduct during the reaction of H₂O with the methyl ligands. At step 158, the deposition chamber is again purged (e.g., by introducing an inert gas) to remove any residual H₂O or by-products from the material. As with the first purge step 154, purging the chamber may not be completely effectual in removing all of the contaminants (e.g., H₂O, C, or H, etc.).

System and methods in accordance with various embodiments can be used in the atomic layer deposition of any material or film on any type of substrate using a wide variety of precursor materials. For example, ALD processes in accordance with embodiments can be used to deposit such materials as oxides, nitrides, and semiconductors in epitaxial, polycrystalline, and amorphous form. Systems and methods in accordance with various embodiments can be used to deposit films for such applications as transistor gate dielectrics, microelectromechanical systems, opto-electronics, diffusion barriers, flat-panel displays such as organic light emitting diodes, interconnect barriers, interconnect seed layers, DRAM and MRAM dielectics, embedded capacitors, other thin films applicable to technologies below the 90 nm node, and electromechanical recording heads. By way of non-limiting example, ALD utilizing flash heating in accordance with various embodiments can be used to deposit such materials as: metals; II-VI compounds (e.g., ZnS, ZnSe, ZnTe, ZnS1-xSex, CaS, SrS, BaS, SrS₁₋ₓSeₓ, CdS, CdTe, MnTe, HgTe, Hg₁₋ₓCdₓTe, Cd₁₋ₓMnₓTe); II-VI based TFEL phosphors (e.g., ZnS:M (where M is Mn, Tb, or Tm), CaS:M (where M is Eu, Ce, Tb, Pb), SrS:M (where M is Ce, Tb, Pb, Mn, Cu); ITT-V compounds (e.g., GaAs, AlAs, AlP, InP, GaP, InAs, AlₓGa₁₋ₓAs, GaₓIn₁₋ₓAs, GaₓIn₁₋ₓP; semiconductor/dielectric nitrides (e.g., AlN, GaN, InN, SiNx); metallic nitrides (TiN, TaN, Ta₃N₅, NbN, MoN); dielectric oxides (e.g., Al₂O₃, TiOx, ZrO₂, DFO₂, Ta₂O₅, Nb₂O₅, Y₂O₃, MgO, CeO₂, SiO₂, La₂O₃, SrTiO₃, BaTiO₃; transparent conductor/semiconductor oxides (e.g., In₂O₃, In₂O₃:Sn, ln₂O₃:F, In₂O₃:Zr, SnO₂, SnO₂:Sb, ZnO, ZnO,:Al, Ba₂O₃, NiO, CoOₓ); superconductor oxides (e.g., YBa₂Cu₃O7-x); other ternary oxides (e.g., LaCoO₃, LaNiO₃); fluorides (e.g., CaF₂, SrF2, ZnF₂); elements (e.g., Si, Ge, Cu, Mo); and other materials (e.g., La₂S₃, PbS, In₂S₃, CuGaS₂, SiC).

A wide variety of precursors can be used to deposit various materials in accordance with embodiments. By way of non-limiting example, precursors including elemental Zn, elemental Cd, elemental S, elemental Se, AlCl, TiCl₄, TzCl₅, TzCl₅, Me₂AlCl, TMA, DMAI, alkyls, diketonates are a small portion of the precursors that can be used. By way of further non-limiting example, many oxygen or nitrogen sources can be used as a second precursor when depositing oxides or nitrides. For example, O₂, H₂O, O₃, and aluminum alkoxides and other materials can be used as an oxygen providing second precursor. In addition, high-density plasma as hereinafter described can be used to generate oxygen and nitrogen for the deposition of oxides, nitrides, and oxynitrides. A mixed high-density microwave excited plasma can be used to generate oxygen or nitrogen radicals for the deposition of high quality oxides, nitrides, and oxynitrides. A mixed high-density excited plasma of an inert gas and an oxygen and/or nitrogen source can be used to generate oxygen and/or nitrogen radicals for the deposition process. For example, mixed high-density plasmas including He/O₂, Ar/O₂, Kr/O₂, Xe/O₂, Ne/O₂ can be used to generate oxygen radicals as the second precursor to deposit oxide materials. Other mixed high-density plasmas suitable for ALD can include, without limitation, inert gas/N₂, inert gas/N₂/H₂, inert gas/NH₃, inert gas/H₂, inert gas/NH₃, inert gas/O₂/NH₃, and inert gas/H₂O.

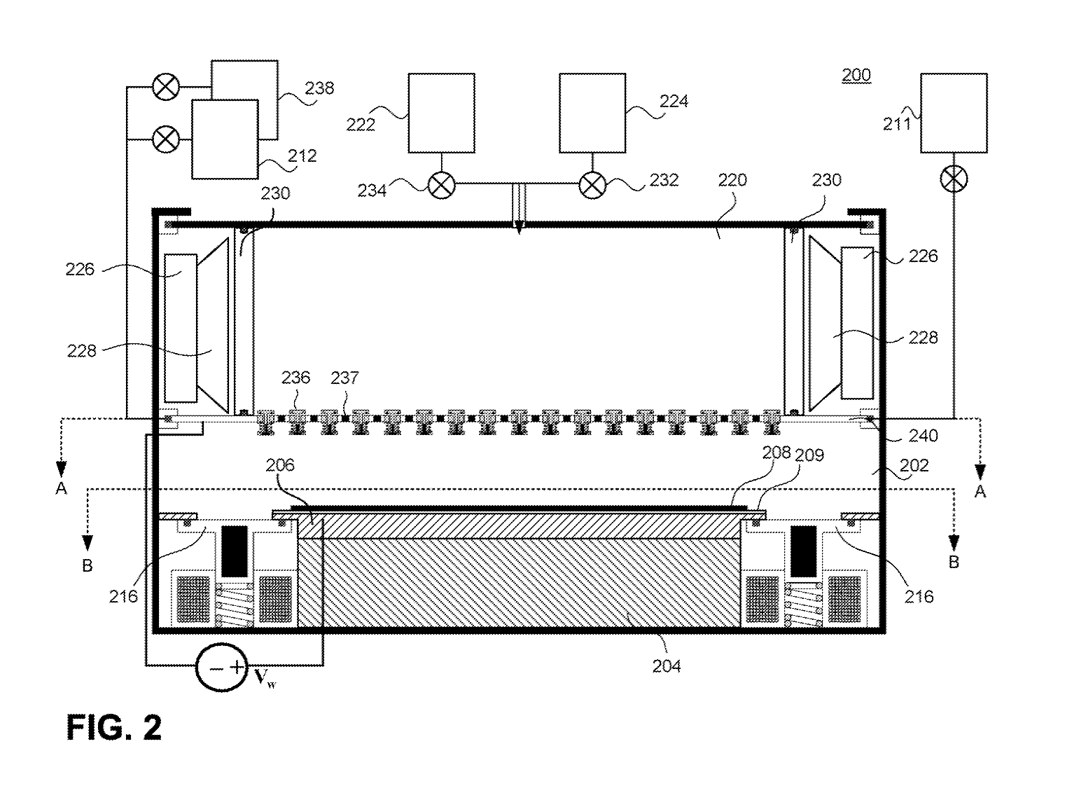

FIG. 2 is a generalized block diagram of a deposition system 200 in accordance with one embodiment. System 200 includes a deposition chamber 202 that can house one or more substrate wafers upon which one or more films are to be deposited. Chamber 202 includes a wafer chuck 204 for supporting and maintaining one or more wafers 208 during the deposition process. Wafer chuck 204 is coupled to a wafer heating element 206 to maintain the substrate at a suitable temperature for deposition thereon. Wafer 208 may be placed on a platen 209 on the chuck and heating element. In one embodiment, the ALD process temperature is in the range of about 250° to 350° C., although any suitable ALD process temperature can be used in accordance with desired implementations.

In one embodiment, chuck 204 is coupled to a voltage bias that can electrostatically hold wafer 208 to the chuck. Other means for maintaining the wafer in position can be used in various embodiments. Container 212 holds the first precursor which can be delivered uniformly over substrate 208 through valves 237 in separation plate 240. A second container 238 can be provided to hold a second first precursor if so desired for a particular implementation. Container 211 holds a purge gas that can be introduced through valves 237 between precursor pulses to aid in purging the deposition chamber.

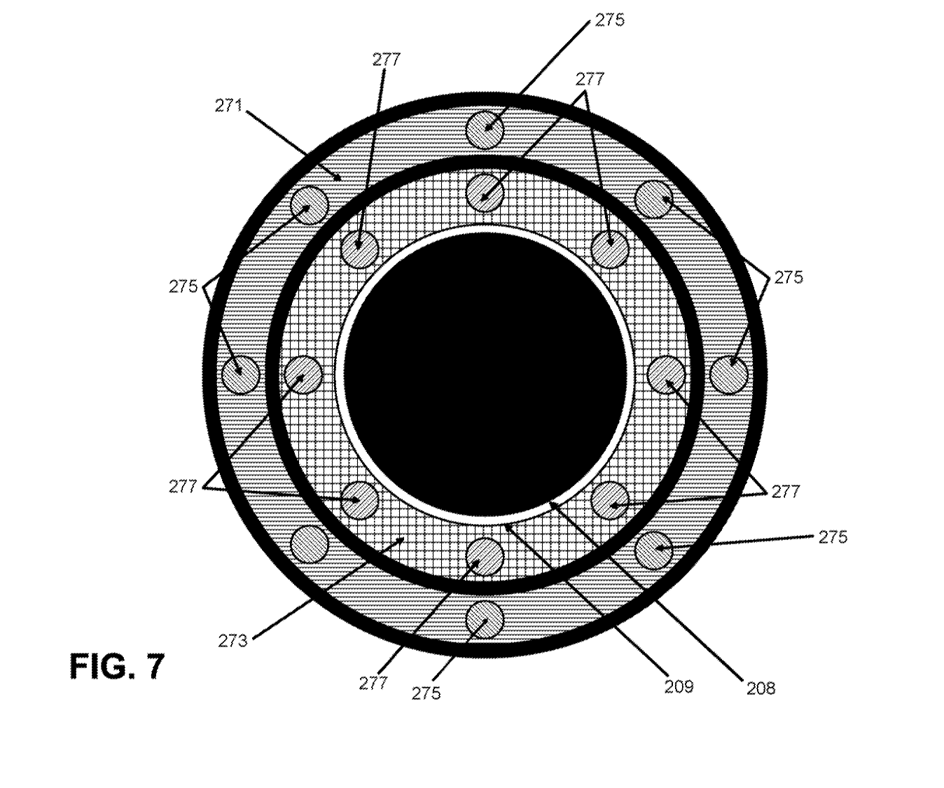

Between precursor pulses and/or after introduction of inert gas into the chamber, excess reactant and by-products can be removed from the chamber through one or more valves 216 connected to pumps (not shown). In one embodiment, system 200 can be formed with a circular chuck 204 surrounded by one or more valve(s) 216. In one embodiment, a single circular valve 216 is used that encircles a circular substrate chuck 204. One or more actuators can be used to open or close valve(s) 216. In FIG. 2, valve(s) 216 is designed to be closed in the raised position. In other embodiments, the top or ring portion of valve(s) 216 can sit above the bottom of the ALD chamber and be open in the raised position. More details regarding valve 216 are shown in FIG. 7.

System 200 further includes a plasma source chamber 220 for the generation of radicals that can serve as the second precursor (reactant) in the deposition process. A first feed gas such as Ar, Xe, Kr, He, etc. can be delivered into chamber 220 from container 222 while a second feed gas such as H₂O, H₂, O₂, or O₃ can be delivered from container 224.

One or more microwave energy source(s) 226 or other suitable energy source (e.g., a radio frequency energy source) provide energy to the chamber through a horn antenna, waveguide, or other mechanism 228 to excite the feed gases and generate the high-density plasma. A dielectric barrier 230 that is impermeable to gases but permeable to microwaves (or RF waves if such an energy source is used) is provided between the energy source and gas mixture. In one embodiment, dielectric barrier 230 is quartz. In one embodiment, dielectric barrier 230 is preferably a material that will not oxidize or nitridize, etc. in the presence of oxygen or nitrogen radicals. Microwave energy source 226 excites the feed gases, forming a high-density mixed plasma in chamber 220. A mixture of an inert feed gas and an oxygen, hydrogen, nitrogen, or other desired reactant carrying second feed gas (e.g., molecular oxygen, O₂) can be provided into the plasma source chamber. Microwave energy source 226 can excite the inert gas and second feed gas to form radicals that can serve as the second reactant in the deposition process. For example, an inert gas and oxygen bearing gas can be provided to the chamber and excited to generate oxygen radicals (O¹D). Ions will also be generated from the first feed gas. These ions can impact the substrate along with the generated radicals to drive surface reactions between the first precursor and radicals (second precursor or reactant).

A plurality of valves 236 are provided in separation plate 240 between the two chambers. The valves can be opened to deliver the radicals and ions to the substrate at the appropriate time during the deposition process. Any number of means for selectively delivering the radicals and ions from the plasma source chamber to the deposition chamber can be used in accordance with various embodiments. The valves as illustrated in FIG. 2 include a ferromagnetic inner material surrounded by solenoid coils to form an electromagnetic valve. A voltage can be applied to the coils of the electromagnet to force the ferromagnetic material upward, thus opening the valve. In one embodiment, separation plate is a showerhead having orifices and/or valves for delivering the first and second precursors and purge gas. In one embodiment, showerhead 240 is made of quartz.

In one embodiment, the high-density mixed plasma can be generated continuously and selectively applied to the substrate by opening and closing valves 236. In other embodiments, plasma generation can be toggled on and off during the process using energy source 226 and/or valves 232 and 234 that regulate the delivery of feed gases to plasma chamber 226. In one embodiment, the timings of the operations of valves 232 and 234, the power to microwave/radio wave generator 226, and valves 236 can include complicated phase relationships with respect to one another in order to optimize the production and timely delivery of radicals to the substrate.

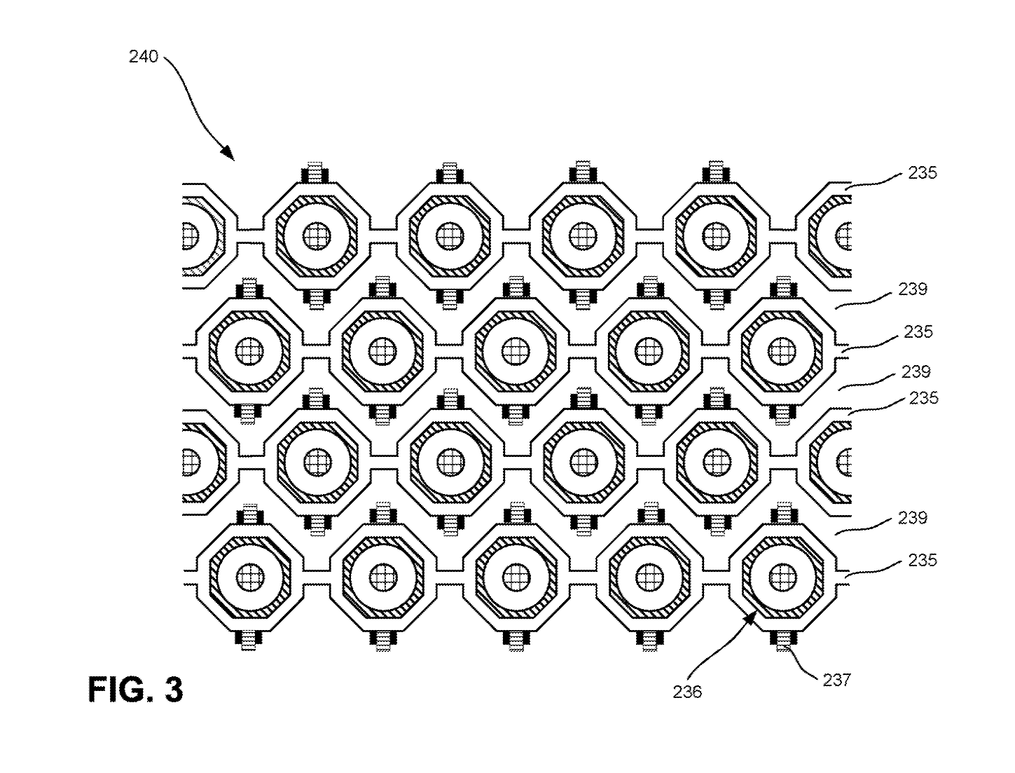

FIG. 3 is a cross-sectional view of a portion of plate 240 taken along line A of FIG. 2. Plate 240 contains a system of ducts, actuator valves, and wiring, etc. for the delivery of the precursors and purge gas. An exemplary arrangement of valves 236 for delivering the second precursor radicals from plasma source chamber 220 and valves 237 for delivering the first precursor is depicted. Various techniques including precision machining, diffusion bonding, and/or precision furnace brazing can be employed to manufacture a plate having an intricate set of ducts as depicted. Vacuum Process Engineering, Inc. of Sacramento, Calif. is a provider of such technologies.

A set of conduits 235 is provided for wiring, etc. that may be necessary to operate valves 236 and/or 237. A set of ducts 239 is provided to deliver the first precursor from chamber 212 and/or 238 to valves 237. The first precursor can be delivered to the deposition chamber through ducts 239 and valves 237. The first precursor can be purged from chamber 202 by introducing a purge gas to the deposition chamber 202 through ducts 239 and valves 237 while evacuating the deposition chamber through valve(s) 216. The second precursor is delivered from above plate 240 to deposition chamber 202 by opening valves 236. In one embodiment, conduits 235 can be used as ducts to deliver gases for the ALD process or to operate the valves.

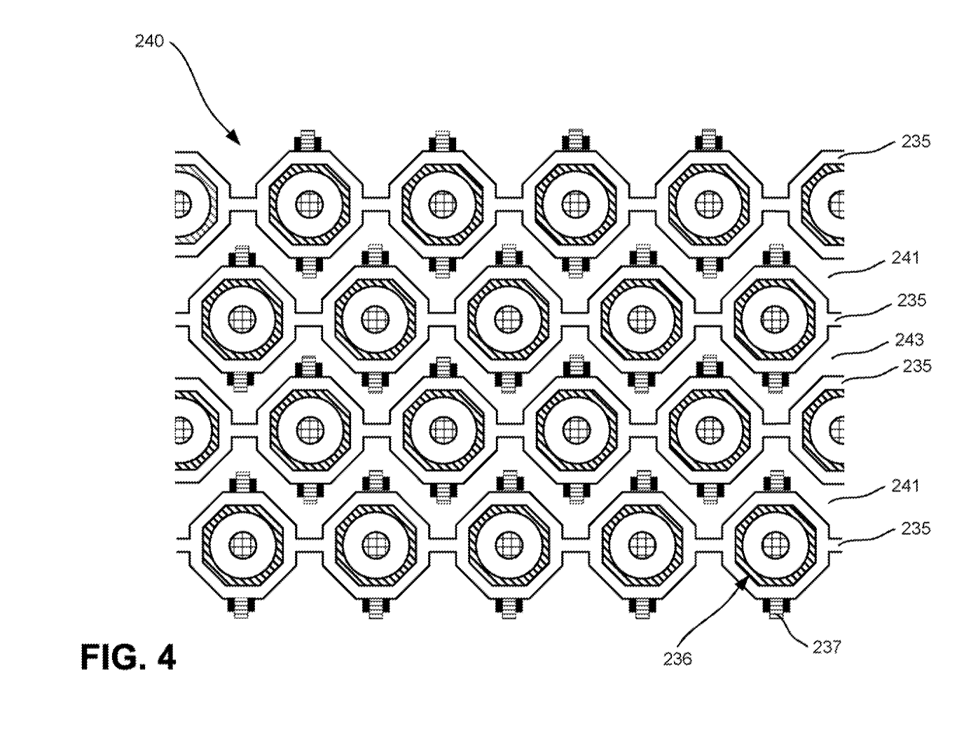

FIG. 4 is another cross-sectional view of a portion of plate 240 taken along line A of FIG. 2 in an embodiment including separate ducts and valves for the first precursor and purge gas. A first set of ducts 241 deliver the first precursor and a second set of ducts 243 therebetween deliver the purge gas. The valves 237 for delivering the first precursor and the purge gas are distributed across plate 240 as shown. An advantage of this arrangement is that ducts carrying both gases, such as ducts 239 in FIG. 3, do not have to be purged or pumped down to lower pressure in each cycle, which allows for shorter cycle times and faster deposition rates. It should be noted that it is advantageous for plate 240 to be as thin as possible, for example just a few millimeters or centimeters. This will minimize the distance that the oxidizing second precursor has to travel before it reaches the substrate. This will minimize the recombination of short lived highly reactive free oxygen radicals that can combine with one another to form O₂ molecules before they reach the substrate surface.

Valves 236 and 237 can take many forms in various embodiments. They can be electrically or mechanically (e.g., pneumatically) driven. If pneumatic valves are used, conduits 235 can include or be replaced with separate inlet and exhaust ducts to the pneumatic control gas (e.g., filtered air or nitrogen). Electric actuators can be of many types, including but not limited to, coil, magnet, piezoelectric, etc. If valves having coil springs or other exposed movable parts are used, care should be taken to avoid particulate generation thereon and subsequent flaking or breaking off of the deposited film onto the wafer causing contamination.

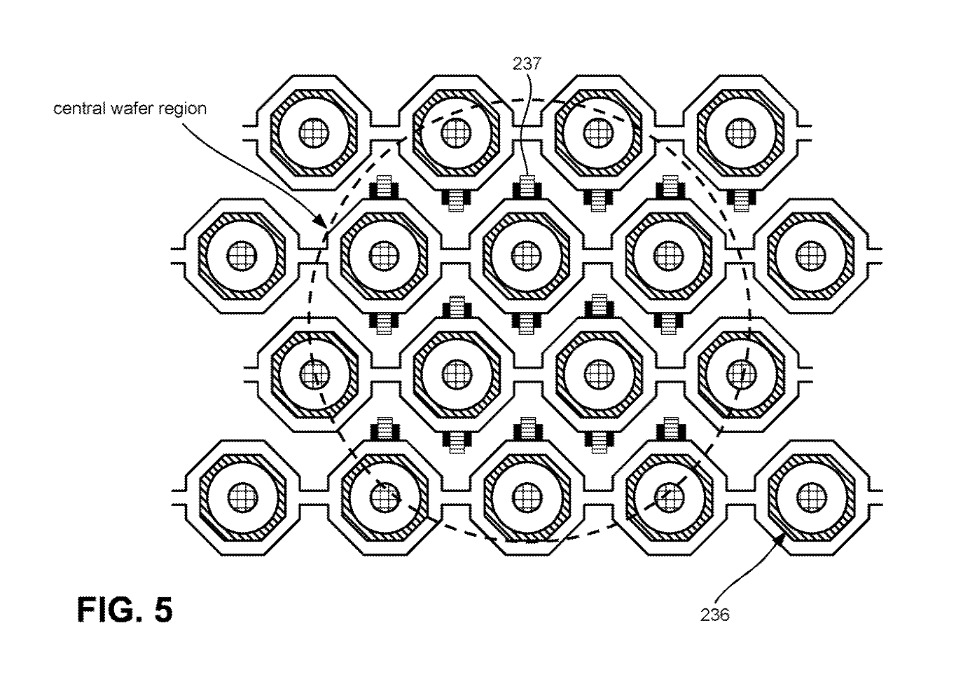

FIG. 5 depicts a cross-sectional view of a portion of plate 240 taken along line A of FIG. 2 in yet another embodiment. In FIG. 5, valves 237 are only used around the central wafer region to deliver the first precursor and purge gas. The various gases can be introduced into the center of the chamber above the wafer and drawn across the substrate surface. The first precursor can react at the surface of the wafer and then be evacuated from the periphery of the chamber through valve(s) 216. In one embodiment the first precursor is evenly distributed across the substrate surface using a valve arrangement as shown in FIGS. 3 and 4. The purge gas will be introduced in a manner as shown in FIG. 5 while evacuating the first precursor out of the chamber through valve(s) 216. The purge gas will be drawn radially across the substrate surface and out through the valves causing an effective and efficient evacuation. In one embodiment, a single purge gas valve is used. The single purge gas valve can be placed in the middle of the deposition chamber (e.g., in middle of plate 240) or some other location. A large central valve bigger than valves 236 and 237 in FIGS. 3 and 4 can be used.

In one embodiment, valves 237 are replaced with orifices and the various gases are controlled through remote valves. The same ducts or separate ducts can be used for the first precursor and the purge gas. In one embodiment, a single valve is used for delivering the first precursor and a separate single valve is used for delivering the purge gas. Both valves can feed into the same or a different duct system. In one embodiment, they both feed into the same duct system and the precursor valve is located downstream from the purge gas valve to aid in evacuation of precursor from the ducts and deposition chamber. Large orifices can be used in place of valves 237, which can provide rapid evacuation and more laminar flow for more uniform distribution resulting in better deposited film thickness uniformity.

Numerous variations and combinations of internal and external valve configurations for each of the feed gases can be used in one or more embodiments. For example, motile valves may be used for valves 236 to quickly deliver the second precursor in order to shorten the distance between radical production and the various points on the substrate surface. Singe external valves could be used for the first precursor and purge gases. Swagelok Semiconductor Services Company of Santa Clara, Calif. is a provider of rapid ALD valves that can be used in one embodiment for one or more of valves 236 and/or 237.

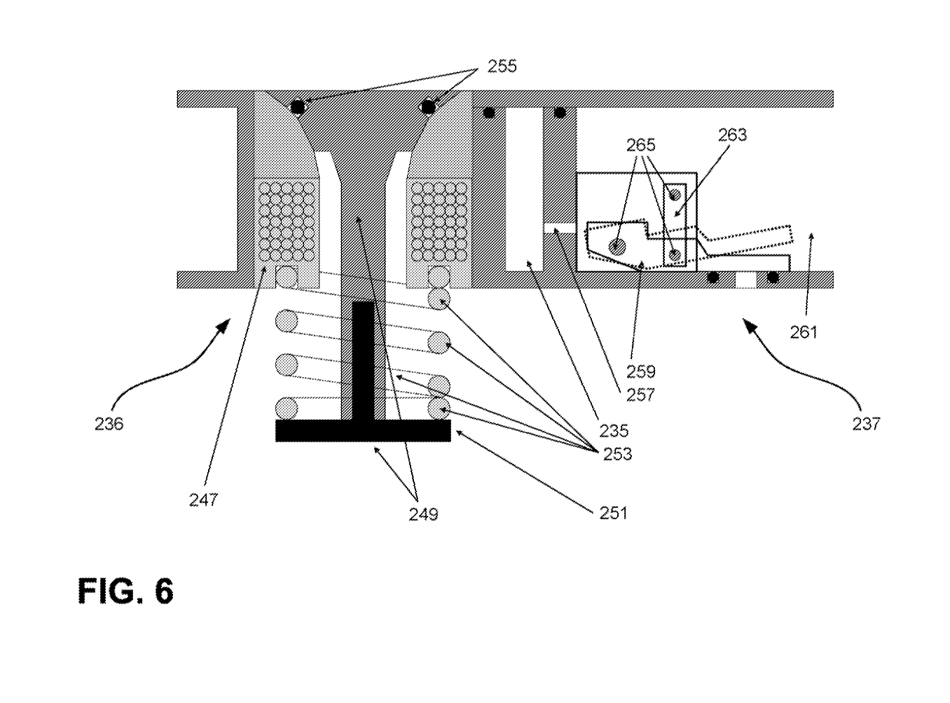

FIG. 6 depicts an exemplary arrangement of a pair of valves 236 and 237 in accordance with one embodiment. Valve 236 is an electromagnetic valve having solenoid coils 247, metal valve stem 249, ferromagnetic material 251, metal springs 253, and O-rings 255. Valve 236 is made flat to the top face of the separate plate 240. In the closed position, valve 236 provides a smooth face for a more ideal chamber for microwave propagation with less reflection of the electromagnetic waves at the valve sites. Conduit 235 and port hole 257 are depicted. In this embodiment, conduit 235 carries wire necessary for operation of valve 237. Valve 237 is a piezolectrically operated valve including piezoelectric actuator 263, hinges 265, shutoff valve 259, and gas duct 261.

In one embodiment, valve(s) 216 is a turbo molecular pump. Turbo molecular pumps can pump down from 1 Atmosphere of pressure to ultra high vacuum pressures as low as 1E-10 Torr, where 760 Torr=1 Atmosphere. Diffusion pumps operate between 150 mTorr and 1E-8 Torr, cryogenic pumps, which are good for removing water vapor and employ charcoal carbon to remove organics, operate between 200 Torr and 1E-10 Torr, dry pumps or root pumps operate between 1 Atmosphere and 1E-3 Torr. Turbo molecular pumps also provide high throughput. Care should be taken to avoid buildup of ALD deposited material on the blades, which can be traveling at speeds exceeding twice the speed of sound, as well as the chamber of these pumps. Failures may occur if the buildup brings these parts into contact with one another. Flakes and other particulates that come into the pumps through exhaust fans can also damage the pumps.

In one embodiment, individual exhaust systems are dedicated to each of the individual precursors to avoid ALD type reactions in the exhaust system. FIG. 7 is a top view of the deposition chamber in one embodiment, taken along line B of FIG. 2. Wafer 208 on substrate paten 209 is depicted. A first ring shaped shutter 271 for the evacuation of the second precursor and a second ring shaped shutter 273 for the evacuation of the first precursor are used. Actuators 275 are used to raise (or lower, depending upon arrangement) shutter 271 to evacuate the second precursor during the appropriate phase of the ALD cycle. Actuators 277 are used to raise or lower shutter 273 to evacuate the first precursor during the appropriate phase of the ALD cycle. In one embodiment, shutter 271 is used for the first precursor and shutter 273 is used for the second. By evacuating the precursors using separate exhaust systems, the buildup of deposits from gaseous reactions in the exhaust chambers can be reduced.

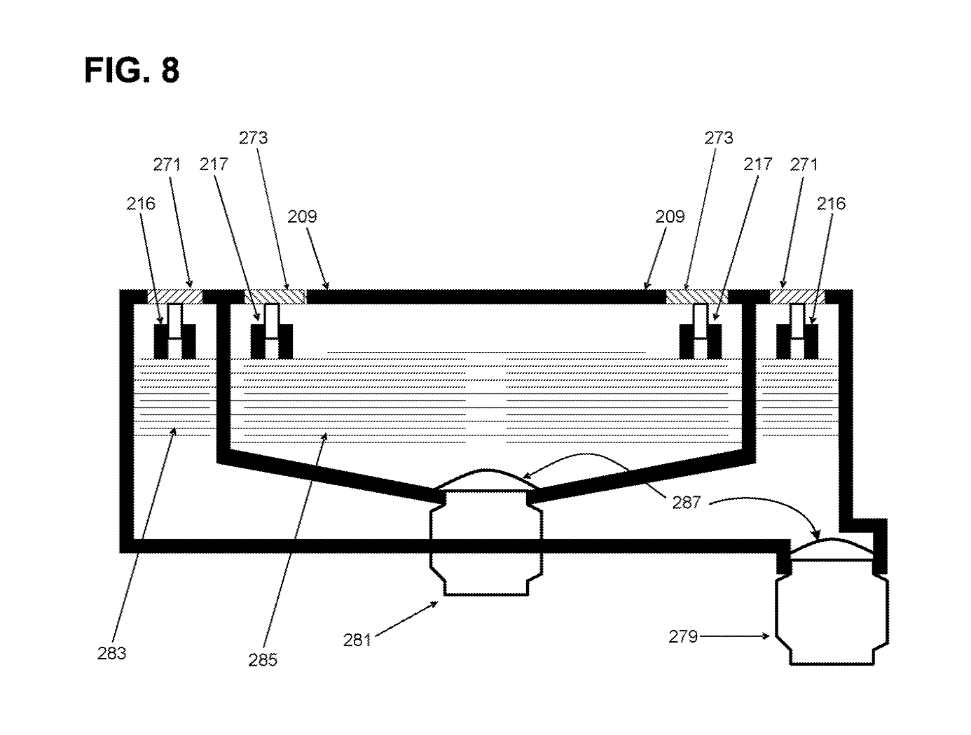

An individual turbo molecular pump can be used for each exhaust system in one embodiment. FIG. 8 is a cross sectional view of a deposition chamber in accordance with one embodiment. Substrate platen 209 is located inside of ring shaped shutter 273, which is located inside of ring shaped shutter 271. A first turbo molecular pump 279 is used to pull the second precursor from the deposition chamber through open shutter 271 by creating a vacuum. A second turbo molecular pump 281 is used to pull the first precursor from the deposition chamber through open shutter 273.

In one embodiment, additional surface area is provided in the exhaust system to collect deposits caused by unreacted gases reacting in the exhaust system. Unreacted gases from the deposition chamber can react and deposit films on the additional surface area provided in the exhaust system before they reach the pumps downstream and cause damage. In FIG. 8, surface absorption plates 283 are provided to collect deposits caused by unreacted second precursor entering through shutter 271. Plates 285 are provided to collect deposits caused by unreacted first precursor. In one embodiment, metallic porous filters 287 are placed before the inlets of pumps 279 and 281 to capture flakes and other particulates before they enter and potentially damage the pumps.

Kr Ion Generating Feed Gas

In one embodiment, krypton (Kr) is used as an inert gas for the generation of oxygen radicals in a high-density mixed plasma to deposit one or more oxide containing layers. An oxide, e.g. aluminum, silicon, or hafnium oxide, can be deposited quickly, efficiently, and with very high density using a Kr and oxygen carrying feed gas (e.g., O₂) mixture, thus resulting in a thick, high quality oxide. For example, silicon oxides deposited from a Kr/O₂ plasma can maintain a good O/Si mixture and have a low interface trap density that is comparable to or less than thermally grown silicon oxide.

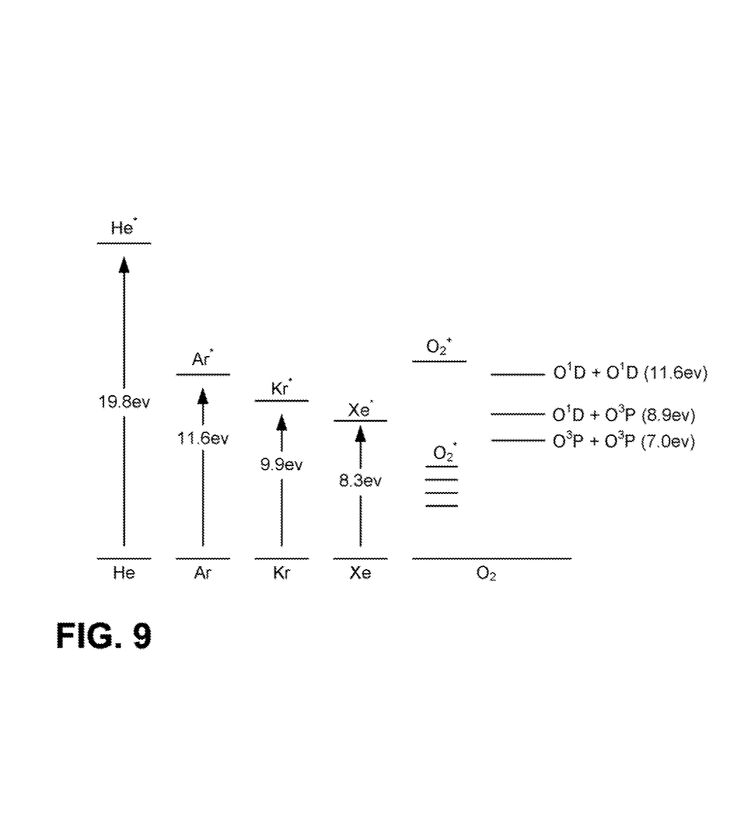

Kr shows improved benefits over other inert gases for the production of oxygen radicals in a high-density mixed plasma. FIG. 9 is an energy diagram illustrating various dissociation energies of oxygen and the metastable states of various inert gases. The dissociation energy of molecular oxygen, O₂, into two oxygen radicals (O¹D+O¹D) is approximately 11.6 eV, while the dissociation energy of molecular oxygen into a molecular oxygen ion, O₂+, is 12.1 eV. The first metastable state of Ar is 11.6 eV, which is closest to the dissociation energy for oxygen radicals (O¹D+O¹D) of the four inert gases. Thus, oxygen radicals (O¹D+O¹D) can be generated from the first metastable state of Ar. Because the energy state (12.1 eV) of a molecular oxygen ion (O₂+) is close to the dissociation energy of oxygen to oxygen radicals (O¹D+O¹D=11.6 eV), however, molecular oxygen ions can be excited by the second or higher metastable state of Ar. This results in the inefficient generation of oxygen radicals in an Ar/O₂ mixed plasma. The resulting plasma will generate a large concentration of molecular oxygen ions in addition to the oxygen radicals. Molecular oxygen ions have a lower oxidation force which leads to slower deposition of oxides and oxides of a poorer quality. Assisted by the bombardment of inert gas ions, the oxidation rate from oxygen radicals is greater than that from oxygen molecules because of the higher reaction rate of oxygen radicals with Si.

The first metastable state of Kr is second closest to the dissociation energy of molecular oxygen into oxygen radicals and can be used to generate oxygen radicals from molecular oxygen. The second or higher metastable states of Kr, unlike Ar, are unable to excite molecular oxygen ions. Therefore, oxygen radicals can be selectively generated in Kr high-density plasma to produce a large concentration of oxygen radicals without also providing a large number of oxygen ions. This results in the deposition of oxide films having very good properties and may also reduce deposition times. The resulting oxides have lower leakage currents, better breakdown field intensity, better charge to breakdown distribution, lower stress-induced leakage current, lower densities of interface trapped charges, and lower densities of bulk trapped charges, as compared to the oxide material produced without the aid of free radicals of oxygen.

Inert gases such as Kr can also be used to deposit very high quality oxynitride films having similar benefits to those set forth above. For example, microwave excited high density Kr/O₂/NH₃ or Kr/O₂/N₂ plasma can be used to deposit nitrides or oxynitrides of silicon, aluminum, hafnium, zirconium, tantalum, or mixed dielectrics such as hafnium silicon oxynitrides, to mention just a few. By using Kr, the improvements over other inert gases as discussed above can be achieved in various embodiments. Nitride films can also be deposited using Kr or other inert gases, where the Kr gas aids in the dissociation of nitrogen gas or nitrogen containing chemicals into nitrogen radicals, and possibly other species. Higher quality conductors such as hafnium nitride or titanium nitride can also be produced by the utilization of nitrogen radicals as a nitriding agent. Employing radical nitridation for ALD deposition of such conductors deposited as gate material(s) over a preformed gate dielectric may also improve the quality of the gate dielectric or reduce the leakage currents in the gate dielectric by both improving the gate dielectric properties and by reducing the growth of the parasitic lower-K interface layer dielectrics that may result in higher leakage currents.

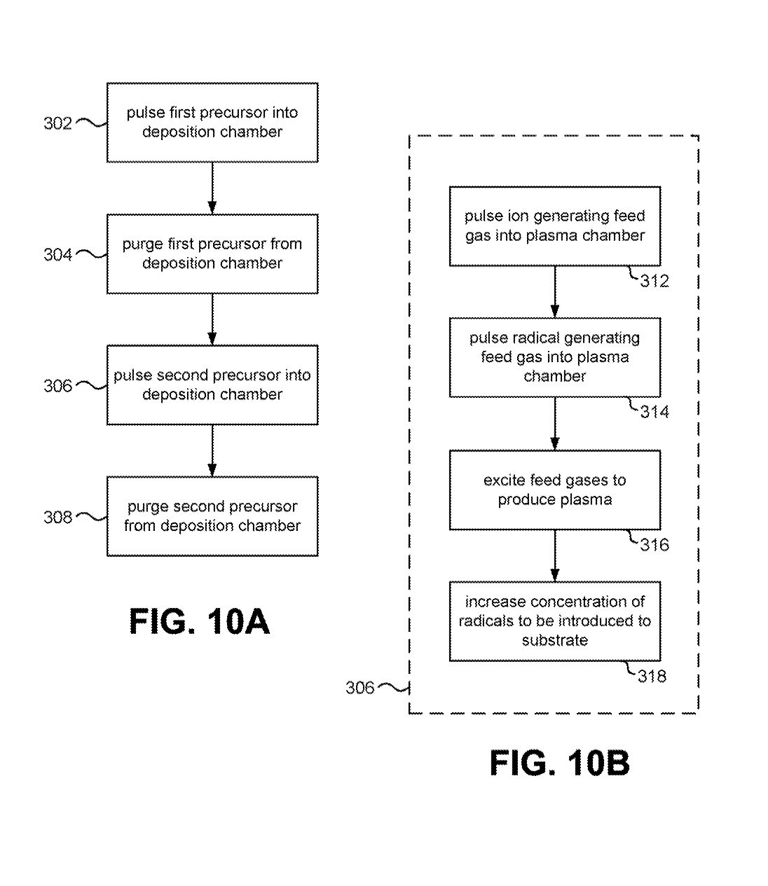

In accordance with various embodiments, one or more techniques can be used to increase the concentration of radicals delivered to the substrate surface to increase the efficiency and quality of a deposited material such as an oxide from oxygen radicals. FIGS. 10A and 10B are flowcharts depicting an ALD process in accordance with one embodiment that utilizes increased concentrations of radicals for delivery to a substrate as a second precursor or reactant. At step 302, a first precursor is introduced into deposition chamber 202 to form a monolayer on the wafer surface. The first precursor is purged from the deposition chamber at step 304. In one embodiment, a purge gas is introduced while evacuating the chamber to purge the first precursor from the chamber at step 304. At step 306, a second precursor is introduced into the deposition chamber that reacts with the monolayer of the first precursor to form a first layer of deposited film. The second precursor is purged from the deposition chamber at step 308.

In accordance with the embodiment depicted in FIGS. 10A and 10B, the second precursor includes radicals generated by exciting ion generating and radical generating feed gases using a microwave or other suitable energy source. FIG. 10B depicts additional details for generating and introducing a second precursor that contains radicals at step 306 of FIG. 10A.

At steps 312 and 314, an ion generating feed gas and a radical generating feed gas are introduced into plasma source chamber 220. The two feed gases are excited by a microwave or other suitable energy source at step 316 to generate plasma containing radicals and ions from the feed gases. For example, a Kr ion generating feed gas and oxygen radical generating feed gas can be used to form oxygen radicals with the aid of Kr ions.

Steps 312 and 314 depict a pulsed introduction and excitation of the feed gases to form the plasma, but other techniques can be used. In one embodiment, the excitation of the feed gases into plasma occurs continuously in the plasma generation chamber. The feed gases can be continuously fed into the plasma deposition chamber and continuously excited to generate plasma. The plasma generated radicals can then be introduced into the deposition chamber in a pulsed fashion by opening and closing valves 236. In another embodiment, the gases are continuously fed into the plasma generation chamber but excited in a pulsed fashion before delivering radicals to the deposition chamber.

Because the concentration of oxygen radicals (relative to molecular oxygen ions and molecular oxygen) affects the quality, efficiency, and rate oxidation of a first metal precursor in ALD deposition of an oxide material, it is desirable to increase the concentration of oxygen radicals relative to these other materials. Accordingly, at step 318, one or more techniques are employed to increase the concentration of radicals relative to other materials that are delivered to the deposition chamber and ultimately the wafer from plasma source chamber 220. For example, an additional energy source can be included in the plasma source chamber to aid in the dissociation of molecular oxygen and oxygen ions into oxygen radicals. Additionally or alternatively, a bias can be applied in the deposition chamber to repel other less desirable ionized materials from the wafer. In one embodiment, step 318 includes applying a bias in the plasma source chamber to attract less desirable charged ions such as oxygen ions away from the deposition chamber. Still yet, in other embodiments a selectively permeable membrane can be included in deposition system 200 to filter less desirable components and thereby increase the radical concentration. In one embodiment, ozone is introduced into the plasma generation chamber and UV light applied to convert some of the ozone into molecular oxygen and radical oxygen. This can be used in conduction with other techniques to to enhance the production of radical oxygen. The ozone can be from a stored source of ozone or produced in another chamber by various methods. For example, UV light and/or a corona discharge system can be used to produce ozone. Titanium oxide and/or iron oxide, which can be used to coat the walls of an ozone generation chamber, can be used as catalysts to enhance the production of ozone in UV light methods. In one embodiment, the ozone production chamber (or at least the inner walls) is made of titanium so that the surface will oxidize into titanium oxide.

As set forth more fully below, any number of these techniques can be used in combination with one another to increase radical concentrations. Additionally, step 318 can include increasing the radical concentration in the plasma generated in plasma source chamber 220 and/or increasing the radical concentration after a mixture of radicals, ions, and less desirable components are introduced into the deposition chamber. Accordingly, in one embodiment step 318 is followed by the introduction of radicals and ions into deposition chamber 202 by opening valves 236. In other embodiments, step 318 is preceded by the introduction of radicals and ions into deposition chamber 202. Various techniques in accordance with embodiments are more fully set forth below for increasing radical concentrations at step 310.

Wafer Chuck Bias

In accordance with one embodiment, the wafer chuck is biased to increase the concentration of preferred species reaching the substrate surface. Referring to FIG. 2, the wafer chuck voltage, Vw, can be used to aid in the deposition of certain films in addition to or in place of holding the wafer in place. For example, if the first precursor carries a positive charge, Vw can be made negative with respect to the chuck while the first precursor is being pulsed in order to attract the first precursor to the wafer. If the precursor does not carry a charge, the dipole moment of the precursor molecule can be exploited to attract the precursor to the wafer surface in a preferred orientation that may, for example, aid in the adhesion of the precursor to the wafer surface. For example, if H₂O is being used as a precursor (e.g., as a second oxidizing precursor), Vw can be positive in order to attract the negative pole provided by the oxygen atoms. In this manner, the oxygen atoms can be attracted to the wafer surface in order to react thereon with the first precursor. The precursor will realign itself in the face of the applied field such that the oxygen bearing side of the compound is positioned toward the substrate. In another embodiment, the wafer voltage can be negative in order to repel undesired reactants or materials from the wafer surface. For example, if a plasma is being used to generate oxygen radicals as previously described, less desirable positively charged molecular oxygen ions can also be generated. In order to increase the concentration of oxygen radicals reaching the wafer surface relative to molecular oxygen ions, a positive bias can be applied to the wafer. The molecular oxygen ions will be repelled by the positive charge, resulting in a higher concentration of oxygen radicals reaching the wafer surface.

Plasma Source Chamber Bias

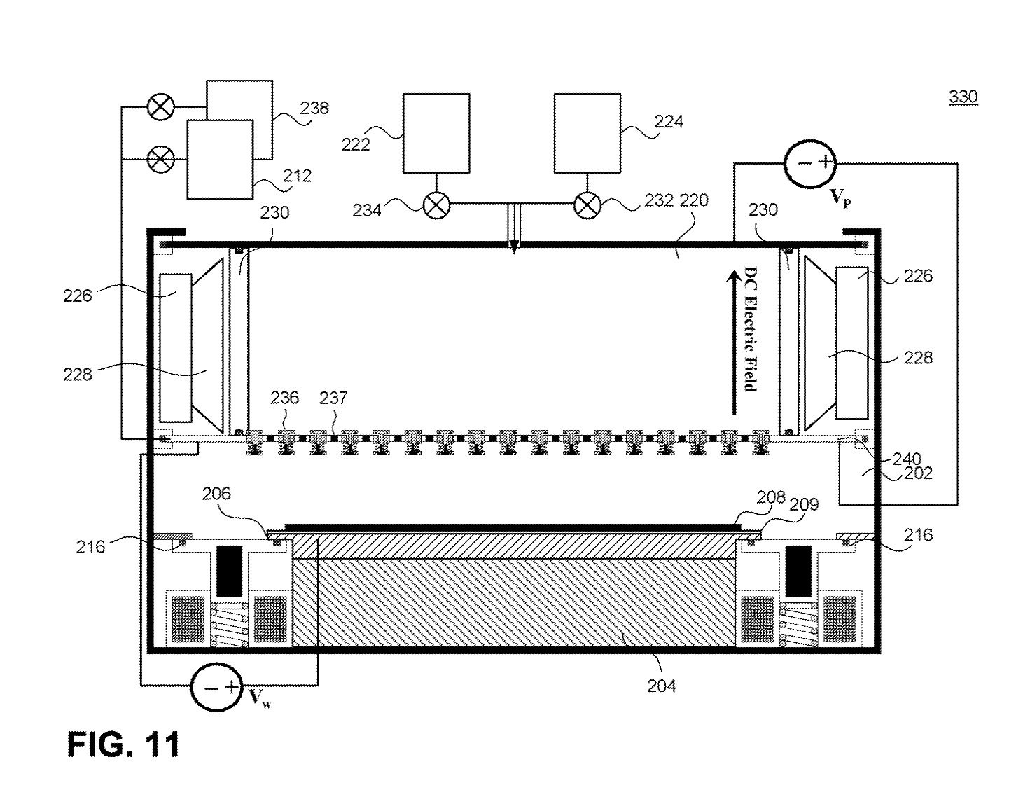

In accordance with one embodiment, an electric field is generated within the plasma source chamber of a deposition system to increase radical concentration. FIG. 11 depicts a deposition system 330 substantially as described with respect to FIG. 2 that further includes an applied voltage to increase the concentration of radicals that can be delivered from plasma source chamber 220. A voltage, Vp, is applied to the plasma source chamber to create a direct current electric field within the chamber. As shown in FIG. 11, Vp is applied with a first node attached at the top of the source chamber and a second node attached at the bottom of the source chamber at separation plate 240. In other embodiments, Vp can be applied in other locations to create an electrical field in the plasma chamber.

If only positive charged ions such as O₂⁻ are to be diverted from the substrate surface, and there are no issues with regard to negatively charged species, then the separation plate 240 bias can be lower than the substrate bias, and the bias of the top plate of the plasma generation chamber lower than the separation plate bias. With such voltage polarities, positive species in the plasma chamber are diverted away from the inlets to the deposition chamber, and positive species that manage to enter the ALD chamber are diverted away from the substrate. Alternatively, if both positively and negatively charged species are to be diverted away from the substrate, then the electric field in the plasma chamber can be set up with a polarity that diverts one type of charged species from entering the deposition chamber, and the electric field in the deposition chamber can be set up to divert the other type of species away from the substrate surface. Deposition of some films may be improved by one set of polarities, while other films may be improved by other sets of polarities.

By applying the positive node of the voltage source to the bottom side of the chamber and the negative node to the top side of the chamber as shown in FIG. 11, an electric field is created within the chamber in the direction shown. The circuit including Vp is broken or open across the plasma source chamber. Electrons will accumulate at the negative node attached at the top of the chamber and be attracted to the positive node of the circuit attached at the separation wall. When sufficiently exited, such as by heating the wire and/or the contact point of the circuit due to the applied voltage, electrons will begin to escape from the wire or contact point because of their attraction to the positive node of the circuit connected to the separation wall. Electrons will enter the chamber from the negative node at the top of the chamber. These electrons will in turn attract and neutralize any positively charged particles that are in the chamber.

For example, the excitation of O₂ in the plasma chamber will result in the dissociation of some O₂ molecules into two oxygen radicals and some O₂ molecules into an electron and a positively charged O₂⁺ ion. The O₂⁺ ions have less oxidation force than oxygen radicals which leads to a less efficient deposition of oxides. By applying the voltage as illustrated in FIG. 11, the O₂⁺ ions will be attracted to the electrons entering the top of the plasma source chamber. This results in the movement of these O₂⁺ ions in the direction of the DC electric field as shown. The O₂⁺ ions will move away from valves 236 and the deposition chamber 202. Consequently, when valves 236 are opened to introduce the generated radicals and inert gas ions, less O₂⁺ ions will be included in the mixture that reaches deposition chamber 220 and ultimately wafer 208. The mixture introduced into the deposition chamber will have a higher concentration of oxygen radicals than a mixture resulting merely from the excitation of the O₂ molecules. The increased oxygen radical concentration will result in a more efficient deposition and a higher density material. Although the foregoing example has been presented with respect to oxides, it will be appreciated that the concepts can be applied to the deposition of other materials as well.

Electrons that accumulate at the metal interface of the cathode need not escape the metal in order to attract the positively charged species. When the electrons do escape from the metal plate, they can neutralize any positively charged species (e.g., converting O₂⁺ to O₂. The electrons that escape and neutralize positively charged species are replenished in the metal by the power supply V_{P}. The DC electrical field established in the plasma chamber that is set up by this power supply is maintained by the presence of the negative charge sheet of the surface of the cathode top plate, and image positive charges on the surface of the anode separation plate. If the field maintaining charges escape from the metal plates, the power supply will replenish the escaped charges and maintain the field.

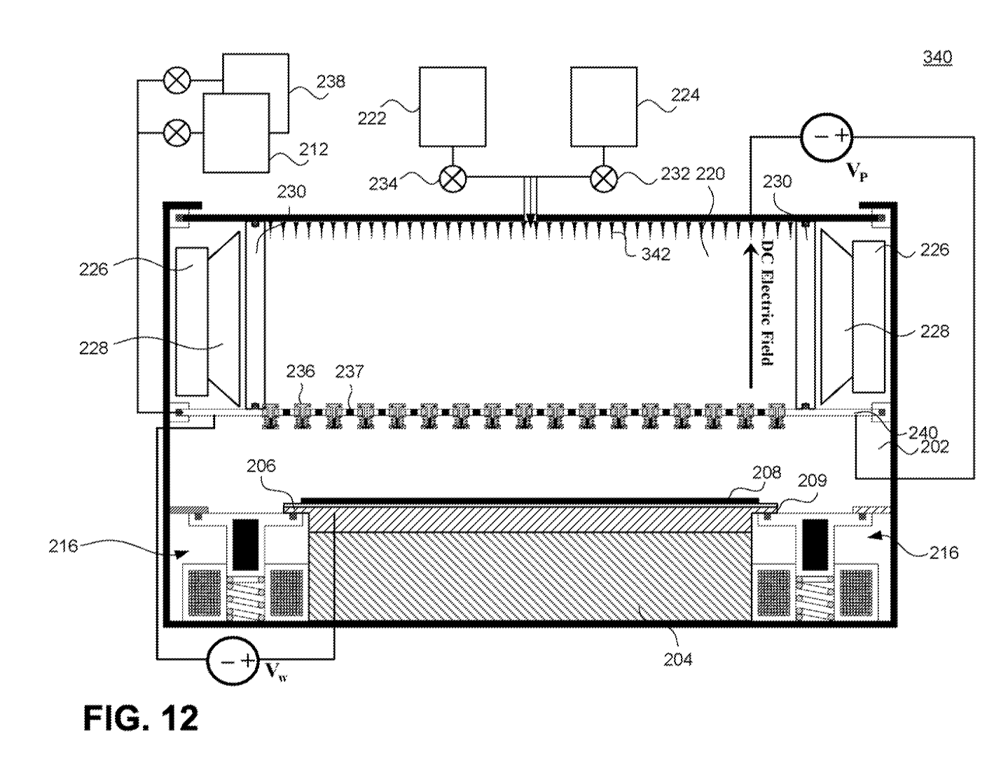

FIG. 12 depicts a deposition system 340 substantially as described with respect to FIGS. 2 and 11 that further includes field emission tips to aid in electron emission. Field emission tips 342 are included within plasma source chamber 220 along the top wall of the chamber. Field emission tips 342 are electrically coupled to Vp. The emission tips are sharply pointed to aid in the release of electrons. As understood in the art, electrons can more easily escape from smaller surface areas. Thus, the emission tips are sharply pointed so that electrons can more easily escape into the plasma source chamber. Emission tips 342 can be formed from a variety of materials but are preferably formed of a material less prone to oxidization. This will minimize or eliminate oxidation on the tips when exposed to a high-density plasma including molecular oxygen ions or oxygen radicals. In one embodiment, the emission tips are formed of silicon while in other embodiments they can be formed of gold, titanium, tungsten, or another metal.

In one embodiment, field emission tips 342 are replaced with a very thin wire running along or substantially parallel to a substantial portion of the top wall of the plasma source chamber. Electrons can escape more easily from a thin wire than from a larger contact point. In another embodiment, emission tips 342 are replaced with carbon nanotubes positioned along the inner portion of the top wall of chamber 220. Carbon nanotubes are excellent emitters of electrons. As opposed to heating an electrode to impart enough energy to electrons so that will escape from the electrode, electrons can escape from carbon nanotubes due to a field emission effect by virtue of the applied electric field. In one embodiment, a light source is incorporated within plasma source chamber 220 to impart light energy on the top wall of the plasma source chamber. The light will strike the surface of the top wall and in accordance with a photoelectric effect, cause electrons to escape from the top wall surface. These electrons will also attract positively charge particles such as O₂⁺ to the top surface and away from deposition chamber 202.

Selectively Permeable Membrane

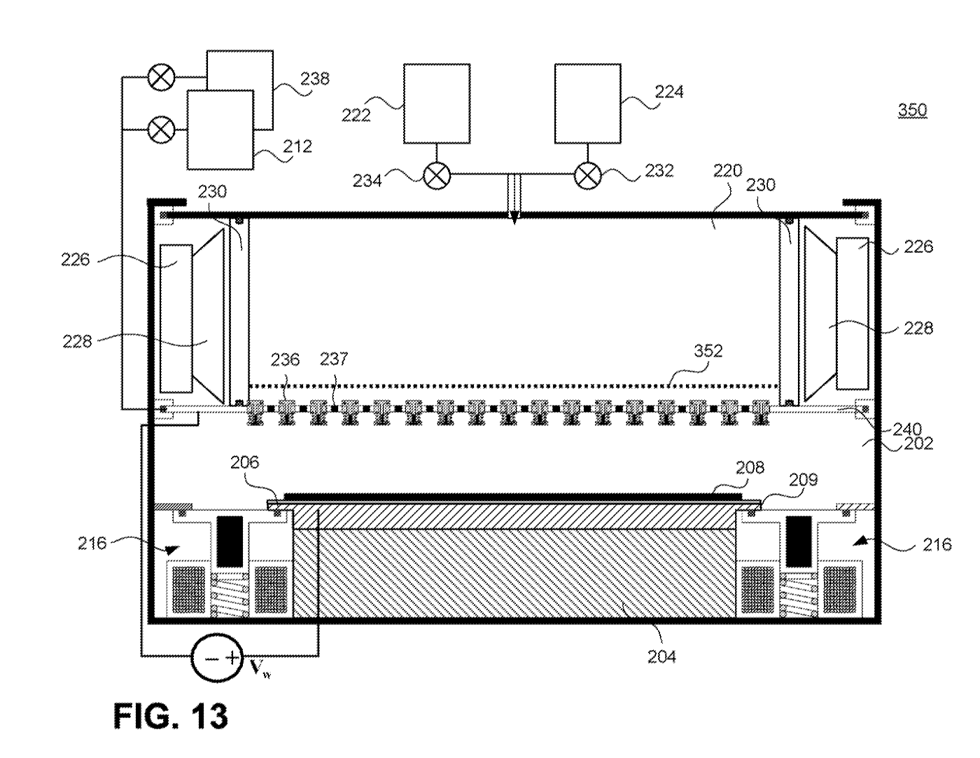

In accordance with one embodiment, a selectively permeable membrane is provided to increase the percentage of oxygen radicals relative to molecular oxygen ions delivered to the substrate surface. FIG. 13 depicts a deposition system 350 substantially as described with respect to FIG. 2 that further includes a selectively permeable membrane 352. Membrane 352 can be formed of various materials in accordance with various embodiments to filter a desired reactant from undesired components in order to deliver a more effective precursor material to the substrate surface.

In one embodiment that includes an oxidizing second precursor, membrane 352 can be a material permeable to radical oxygen but impermeable to materials such as molecular oxygen and molecular oxygen ions. An exemplary deposition process may include the introduction of a first precursor material (e.g., an aluminum, hafnium, or silicon containing material) followed by the introduction of a second oxygen containing precursor to oxidize the substrate surface to form a material such as SiO₂, HfO₂, or Al₂O₃. The second precursor can be an oxygen radical containing mixture generated using a high-density plasma generation technique as previously described. This mixture may contain molecular oxygen and molecular oxygen ions in addition to oxygen radicals. When valves 236 are opened to introduce the oxidizing precursor, the plasma mixture will pass through membrane 352 where the molecular oxygen and molecular oxygen ions can be filtered. A greater concentration of oxygen radicals will be present in the resulting mixture introduced into the deposition chamber and to the substrate surface. In this manner, a more efficient deposition of a higher quality oxide material can occur.

In one embodiment, membrane 352 can be placed in deposition chamber as opposed to plasma source chamber 202 as shown in FIG. 13. In such an embodiment, the membrane can be placed close to valves 236 to filter the undesired components before they reach the substrate surface.

Energy Source for Dissociation

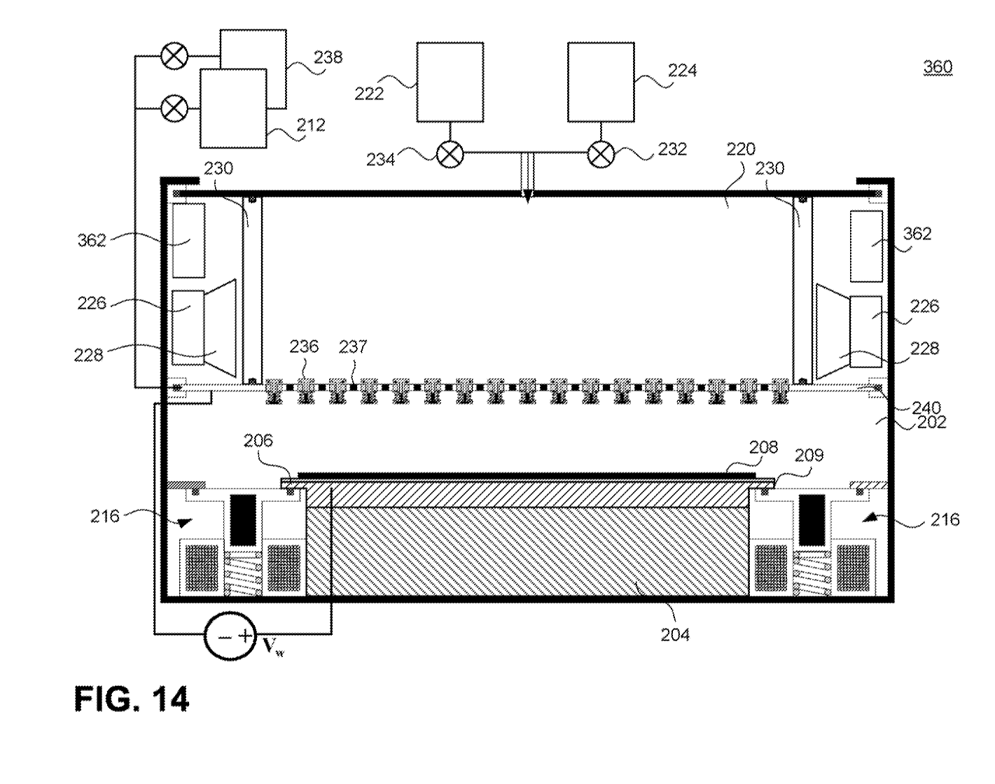

In accordance with one embodiment, an additional energy source is provided in the plasma source chamber of a deposition system to increase radical concentration used as second reactant or precursor. FIG. 14 depicts a deposition system 360 substantially as described with respect to FIG. 2 that further includes one or more energy source(s) 362 to aid in the dissociation of oxygen into oxygen radicals or other molecular components into reactive radicals. An appropriate energy type and level is delivered to the plasma chamber to break down a less desired molecule into a more reactive radical. Various energy sources can be used in accordance with implementations to generate the desired radical.

In one embodiment, energy source(s) 362 is an ultraviolet (UV) light source such as a UV lamp. The UV lamp can be turned on during the excitation of the feed gases to generate the high-density plasma. As previously discussed with respect to an oxidizing second precursor, some molecular oxygen will break down into less desirable molecular oxygen ions. Furthermore, some oxygen radicals will recombine with other radicals or molecular oxygen ions to form molecular oxygen and molecular oxygen ions. When generating oxygen radicals to introduce to the substrate surface, the energy from energy source(s) 362 can excite and dissociate molecular oxygen ions and molecular oxygen into oxygen radicals.

In order to provide good performance, energy source(s) 362, such as a UV lamp, should be tuned to achieve the desired dissociation. As previously discussed, the dissociation energy of oxygen into two oxygen radicals (O¹D+O¹D) is 11.6 ev. Applying e=hf (where h is plank's constant, f is the frequency, and e is the energy of the photon) and λf=c (where λ is the wavelength, f is the frequency, and c is the speed of light), it can be determined that a wavelength of UV light equal to 107 nanometers has frequency components corresponding to the resonant frequency of the oxygen bonds. However, additional thermal energy (equal to Boltzman's constant (k_{b})*temperature) will exist in chamber 220 while applying the UV light. This additional energy may be sufficient in some cases to increase the excitation of the oxygen to begin generating undesired molecular oxygen ions. Accordingly, the wavelength of UV light introduced into chamber may be increased slightly to offset these thermal effects (increased wavelength will result in less excitation).

Accordingly, a larger concentration of oxygen radicals can be generated and delivered to the substrate surface during the second phase of the deposition process. It should be noted that wavelengths of light that are less than 107 nanometers (higher energy) may cause the dissociation of molecular oxygen into oxygen ions instead of oxygen radicals. Accordingly, the light source should be chosen to produce a spectrum of light as close to or slightly more than 107 nanometers for the dissociation to oxygen radicals.

In one embodiment, a deposition system such as described in FIG. 3 can be inverted or rotated 180° relative to gravity. In this scenario, the wafer chuck is positioned above, rather than below, the showerheads for introduction of the first precursor and the plasma source chamber for introduction of the second precursor. An inverted chamber can further increase the concentration of radicals relative to other less reactive molecular components delivered to the substrate surface. For example, in a high-density plasma used to deliver oxygen radicals as an oxidizing second precursor, less desirable O₂+ ions will be created and some molecular oxygen will not dissociate (or will form from the recombination of oxygen radicals or oxygen ions and electrons). Molecular oxygen and molecular oxygen ions are heavier than oxygen radicals. Thus, these components of the plasma will tend to remain at the bottom of the plasma source chamber and not be released to the deposition chamber through the valves. The higher concentration of oxygen radicals introduced into the deposition chamber can increase the efficiency and quality of the deposited oxide.

It will be appreciated that many of the techniques described herein can be combined in various ways for various implementations. For example, a plasma source chamber bias can be used in combination with one or more of a wafer bias, selectively permeable membrane, and additional energy source.

Flash Heating

In one embodiment, a flash heating mechanism is used to flash heat a substrate surface during an ALD process. A flash lamp, for example, is capable of heating the surface of a deposited material without substantially raising the bulk substrate temperature. In this manner, contaminants can be excited and released from the surface without raising the bulk substrate temperature. This a significant improvement over conventional methods of releasing contaminants or annealing using traditional methods such as rapid thermal processing (RTP) including spike annealing or bulk substrate heating. Heating the entire substrate has several disadvantages that can lead to inferior film properties.

If a continuous high temperature is used during deposition, precursors may move on the substrate surface resulting in agglomeration and non-continuous films. At a high enough temperature, the precursors may begin to react in the gaseous phase leading to a chemical vapor deposition like process. The resulting films will not be deposited uniformly at a rate of one monolayer or less. Additionally, if the bulk temperature is raised to a high level, significant diffusion of dopants and inter-diffusion of silicon atoms into Hi-K dielectrics and metal atoms into silicon or poly-silicon can occur.

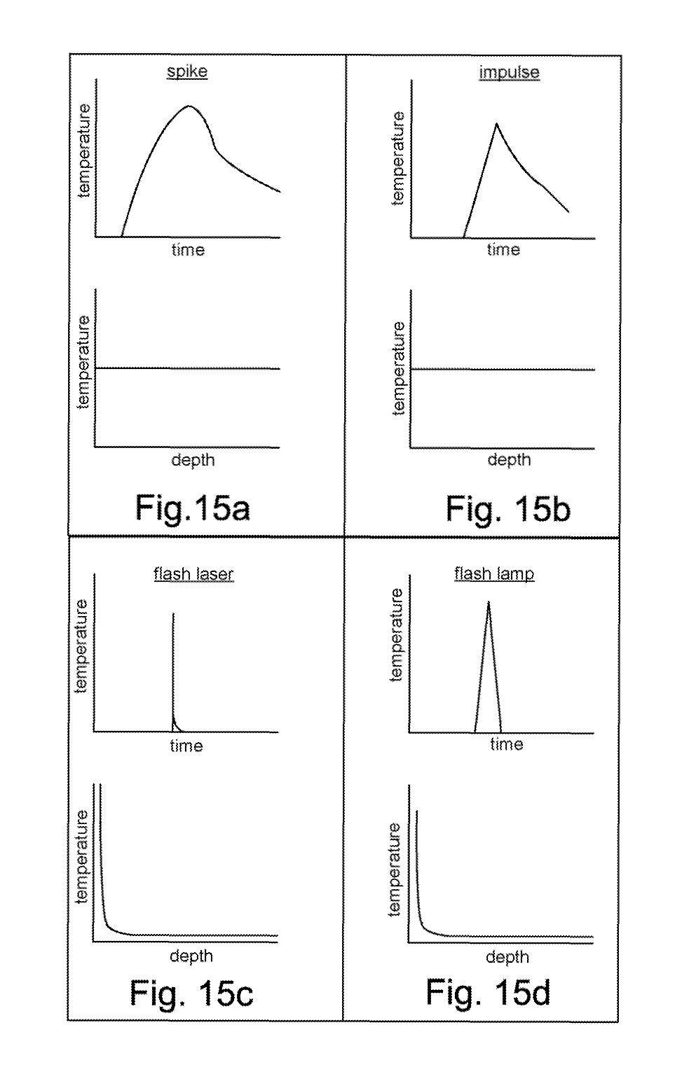

A flash lamp system, however, is capable of quickly raising just the surface temperature of the substrate and thus, avoiding these negative effects. FIGS. 15A-15D depict heating process times and heating depths for various rapid thermal processing techniques as well as flash laser and lamp techniques in accordance with embodiments of the present disclosure. Each of FIGS. 9A-D depicts a first graph illustrating the temperature generated by application of the respective heat source versus time. Each of the Figures also includes a second graph illustrating the temperature of the wafer or substrate versus the depth of the wafer.

A spike annealing technique (e.g., using tungsten-halogen lamps) as depicted in FIG. 15A has a process time on the order of 1.5 seconds or more. The spike annealing heat source is applied for a significant amount of time to raise the wafer temperature. As illustrated, spike annealing raises the entire substrate (including the bulk and surface of the wafer) to an elevated and uniform temperature, independent of depth. Impulse annealing, depicted in FIG. 15B, shows improvement over spike annealing for application in low temperature ALD but sill has a process time on the order to 0.3 seconds. Additionally, impulse annealing also raises the temperature of the entire substrate including bulk and surface.

By contrast, laser and flash lamp techniques in accordance with embodiments are capable of raising just the surface temperature of a wafer and/or deposited materials in time periods on the order of 1 to 3 ms for flash lamp systems and 10⁻⁹ seconds for laser systems. A laser anneal is performed with a very short duration laser pulse as illustrated in FIG. 15C. The laser pulse is capable of raising just the surface of the substrate to a very high temperature in periods of around 10⁻⁹ seconds. As depicted, the wafer is only heated to a limited depth. The bulk substrate temperature is not significantly affected by application of the laser. A flash lamp anneal, depicted in FIG. 15D, is performed with a very short duration pulse from one or more flash lamps. The flash lamp(s) are capable of raising just the substrate surface temperature to a very high temperature in periods of 1 to 3 ms. As with the laser technique, the bulk substrate temperature is not significantly affected by application of the flash lamp. Because the bulk of the substrate is not heated during the flash lamp or laser anneal, the bulk of the substrate can act as a heat sink after application of the laser or lamp pulse to rapidly cool the substrate surface so that the ALD process can quickly continue.

An exemplary flash lamp system that can be used in accordance with various embodiments is described in “ENGINEERING ULTRA-SHALLOW JUNCTIONS USING FRTP,” Camm et al., Vortek Industries Limited, Published by IEEE, 2002. In one embodiment, a water-wall flash lamp system, including multiple lamps with flowing water and gas is used. The system includes a small number of ultra-high power water-wall flash lamps. The high-power lamps can provide uniform heating to raise just the substrate surface temperature. In one embodiment, the flash lamp system is capable of raising the surface temperature at a rate of approximately 106° C./s. Thus, a flash lamp system can raise the surface temperature from a nominal 300° C. used during deposition to approximately 1350° C. in a time period of approximately 1 ms. It will be appreciated that heating rates above and below 106° C./s can be used in accordance with various embodiments. Additionally, the time period for application of the flash lamp can be varied by embodiment and application. For example, in one embodiment an exposure time of 1-4 ms can be used to raise the substrate surface temperature to between 1350° C. and 1500° C. The length of exposure of the substrate to the flash lamp can be adjusted to vary the peak temperature as well as the amount of time the surface is exposed to the increased temperature. In various applications, it may be desirable to increase the exposure time to increase the amount of contaminants released from the surface. However, the length of time and peak temperature should be chosen so as not to induce diffusion of dopants and other residual effects.

In another embodiment, a flash heating system is implemented using one or more lasers in place of flash lamps. Like a flash lamp system, a laser system is capable of heating just the surface of the substrate, without significantly raising the temperature of the bulk. Processing times for a laser are on the order of 10⁻⁹ s. For example, a laser can be used to raise the surface temperature from 200° or 300° C. to approximately 1350° C. in this time period or less. A laser has a small effective application area, and thus, can only heat a portion of a substrate surface at a given time. Accordingly, the laser can be raster scanned across the substrate or the substrate scanned across the laser in order to apply the laser to all or substantially all of the substrate surface. It should be noted that a laser may cause temperature gradients across the wafer in addition to increasing the processing time because of scanning. In one embodiment, multiple lasers are used to avoid scanning the laser(s) and/or moving the substrate under the laser(s)

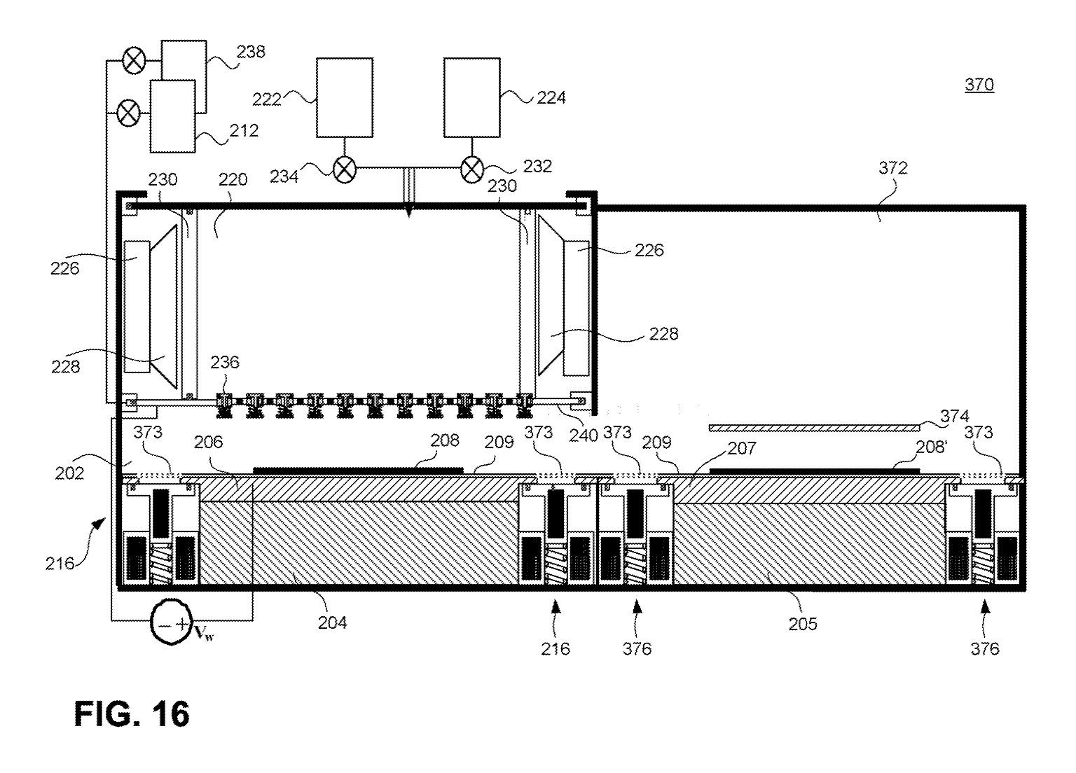

FIG. 16 depicts a deposition system 370 in accordance with one embodiment. System 370 includes a plasma source chamber 220 and deposition chamber 202 substantially as described with respect to FIG. 2. System 370 further includes a heating or annealing chamber 372. Chamber 372 houses one or more flash heat source(s) 374, which can include flash lamps or lasers.

In one embodiment, system 370 is substantially circular or ovular as previously described. Platen 209 (or other substrate support mechanism), disposed on wafer chucks 204 and 205, also substantially circular or oval, spins so that wafer 208 can be moved between deposition chamber 202 and heating chamber 372 at the appropriate points during the ALD process. In such an embodiment, an ALD process can include the introduction of a first precursor through showerhead 240 that is adsorbed on substrate 208. After purging, the substrate surface can be oxidized by the introduction of oxygen or other radicals as a second precursor to deposit a layer of the desired film on the substrate. Before, after, or as the second precursor is purged from the deposition chamber through one or more valves 216, wafer 208 can be rotated into flash heating chamber 372. Wafer 208 at its second position in chamber 372 is denoted as 208′. A short pulse of heat can be applied from flash lamp or laser 804 to excite and release contaminants including residual precursor agents and byproducts. These released contaminants can be removed from heating chamber 372 through one or more valves 376. In one embodiment, valve 376 is a single circular valve as depicted in FIGS. 7 and 8, but with a single ring. In other embodiments, valve 376 can include multiple rings.

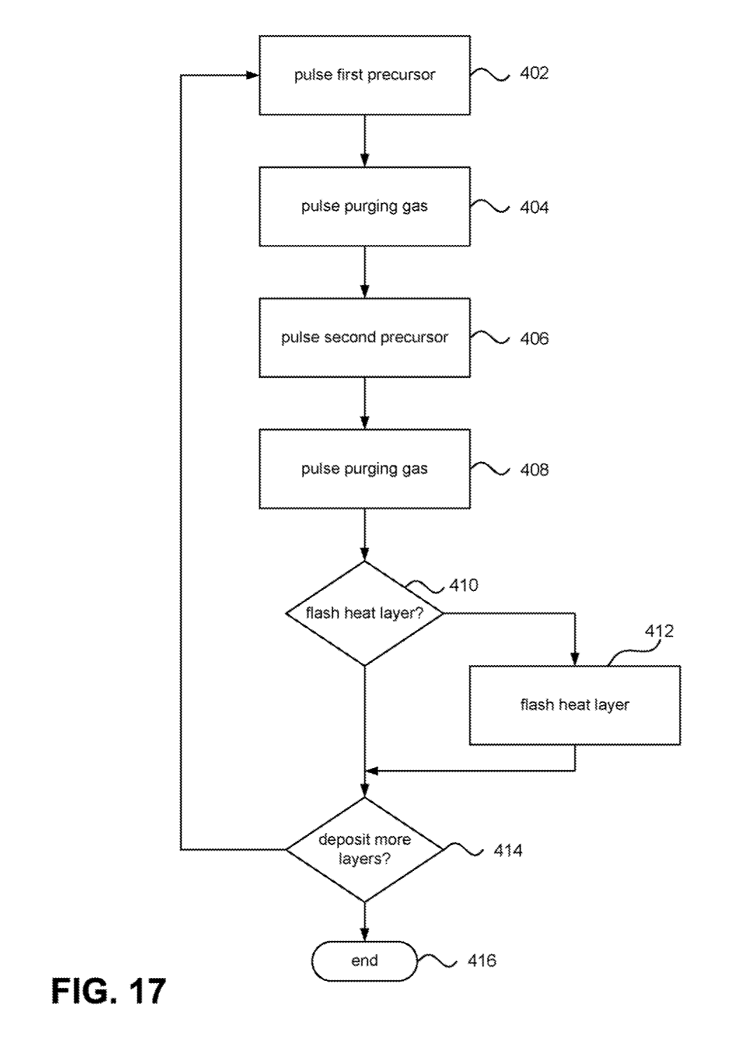

FIG. 17 is a flowchart of an atomic layer deposition process in accordance with one embodiment. The process depicted in FIG. 17 can be used to deposit any film capable of deposition using an atomic layer deposition technique as previously discussed. Additionally, the process can be used to deposit films on various types of substrates. It will be appreciated by one of ordinary skill in the art that the present disclosure is not limited to the deposition of any particular film type on any particular type of substrate. In accordance with various embodiments, the substrate for which the process is performed can be heated to a suitable temperature for the deposition process. For example, in one embodiment, the substrate is heated to a temperature approximately between 100° C. and 200° C. In other embodiments a temperature in the range of 60° C. to 350° C. will be suitable for deposition, while in yet other embodiments the temperature may exceed 400° C.

The process of FIG. 17 begins at step 402 with the introduction of the first precursor which is chemisorbed on the substrate surface. For example, a TMA precursor gas can be pulsed into the deposition chamber containing the substrate to deposit an aluminum containing film. At step 404, the deposition chamber is purged to remove any remaining precursor and/or by-products generated during the first surface reaction. After purging the chamber, a second precursor is introduced to the chamber at step 406. For example, water or another oxygen containing precursor such as oxygen radicals from a high-density plasma can be pulsed into the chamber in order to deposit an oxide material onto the substrate. After introduction of the second precursor, the deposition chamber is again purged at step 408 to remove any remaining precursor or contaminants remaining after the second surface reaction.

At step 410, a determination is made as to whether to flash heat the surface of the deposited material to remove any contaminants. In one embodiment, the material is flash heated after a predetermined number of cycles. In one embodiment, the predetermined number of cycles is one, such that the surface is flash heated after every cycle. By flash heating the surface after every cycle, a larger percentage of contaminants can be removed from the deposited material than if the substrate or surface of the deposited material is only heated after a number of cycles. However, by increasing the frequency of flash heating the surface, the processing time for the overall deposition process will be increased. Accordingly, in other embodiments, the predetermined number of cycles can be increased. In one embodiment, the surface is flash heated after every 2 cycles. In yet another embodiment, the surface is flash heated after every 3 or 4 cycles. In still another embodiment, the predetermined number of cycles is selected to be any number less than 25.

Although not quite as effective as flash heating after every cycle to remove contaminants, flash heating the surface after every few cycles (e.g., about 2 to 25 cycles) can release contaminants from the deposited material. Energy from the flash lamp or laser in the form of heat can reach below the surface of the last deposited layer to excite contaminant particles present in the material at levels below the surface. The heat can excite the particles to a sufficient degree to dislodge them from the material so that they may escape from the surface.

It is preferred that the number of cycles between flash heating be limited so that a larger percentage of contaminant particles can be excited and removed from the deposited material. As the flash heating mechanism will only heat the deposited material to a limited depth, particles below a certain depth will not be sufficiently excited by application of the flash heat to dislodge and escape the material. If the duration of application of the heat is increased beyond a certain level in order to excite these particles, the substrate will begin to heat up, having the negative effects as previously discussed. Additionally, a minimum amount of time must elapse for the substrate to cool to a sufficiently low level for the next deposition cycle. Any extra time incurred while waiting for the substrate to cool can increase processing times. Additionally, if the substrate is not allowed to cool to a level suitable for ALD, the process can become more like a chemical vapor deposition process. The precursors may begin to react in the gaseous phase and the resulting films will not be deposited at a uniform rate of about one monolayer or less per cycle.

If the predetermined number of cycles has elapsed, the surface of the deposited material is flash heated at step 412. In one embodiment, the substrate is flash heated by using one or more suitable flash lamp(s) or laser(s) as previously described with respect to FIGS. 15-16. The flash heat can quickly raise the surface temperature to release contaminants. In one embodiment, a flash lamp or laser raises the temperature of the wafer surface to 1350° C. In another embodiment, a laser can be used to flash heat the surface of the substrate as also described with respect to FIGS. 15-16. After flash heating the substrate surface, the chamber housing the substrate can be purged. In embodiments utilizing a single chamber for both deposition and flash heating, the single chamber can be purged, for example, by introducing an inert purging gas to the chamber. In embodiments utilizing separate chambers, the flash heating chamber can be purged, for example, by introducing an inert purging gas to the chamber.

After removing the released contaminants from the chamber, the process proceeds to step 414 where a determination is made as to whether more layers are to be deposited (or whether the deposited film has reached a desired thickness). If no more layers are to be deposited, the process completes at step 416. If more layers are to be deposited, the process returns to step 402, where the first precursor is pulsed into the chamber.

It will be appreciated that flash heating techniques in accordance with embodiments can be combined with various other techniques described herein including high-density plasma deposition techniques.

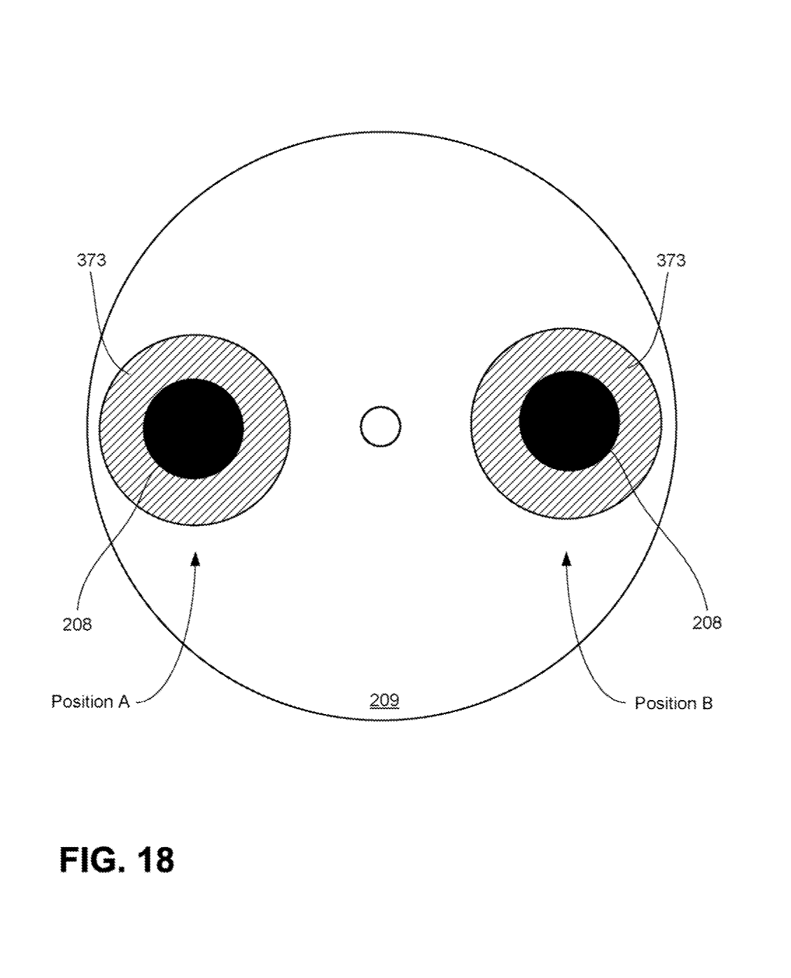

FIG. 18 is a top view of deposition system 370 in one embodiment, depicting the upper surface of circular platen 209. In the embodiment of FIG. 18, platen 209 extends from and over valve 206 at the left hand side of deposition chamber 202 to the right hand side of annealing chamber 372 over valve 376 as shown in FIG. 16. Platen 209 will rotate above valve 216, valve 376, and wafer chucks 204 and 205 (including heating elements 206 and 207). FIG. 18 depicts a first wafer 208 in a first position designated as Position A. Position A may correspond to the location of wafer 208 within deposition chamber 202 of FIG. 16. FIG. 18 also depicts a second wafer 211 in a second position, Position B, which may correspond to the location of wafer 208′ in FIG. 16. Position B corresponds to the wafer's location within annealing chamber 372. As one wafer undergoes deposition, another can undergo annealing. Platen 209 can be rotated to alternately place wafers in the annealing chamber and deposition chamber.

A single ring or shutter 373 is depicted around wafer 208 and wafer 211. When the shutter 373 around wafer 208 or wafer 211 is aligned with circular valve 216, it can be opened (along with valve 216) to purge contaminants from the deposition chamber. In Position B, when shutter 373 aligns with valve 376, contaminants can be purged from the annealing chamber by opening the shutter and valve. In one embodiment, shutter 373 is a mesh material to allow contaminants to pass through. Valve 216 can be actuated to allow contaminants to be purged from deposition chamber 202 at the appropriate times. In one embodiment, shutter 373 is made of a plurality of thin wires or lines rather than a mesh material. The thin wires can extend radially relative to the center of a wafer and run parallel to the wafer surface. The wires can be upwardly concave with respect to the wafer surface. In yet another embodiment, the entire surface of platen 209 can be mesh or made of thin metal lines so that contaminants can readily pass through to be evacuated by valves 216 and 376.

In one embodiment, the entire assembly including wafer chuck 204, heating elements 206 and 207, platen 209, and valves 216 and 376 can rotate together. In such an embodiment, shutters 373 are not necessary. Reference numbers 373 can represent the upper surfaces of valve 216 and/or 376 directly, which will move with the wafers. For example, reference 373 in Position A may represent a ring of valve 216. When the wafer is in Position A within deposition chamber 202, valve 216 can be used to purge gases and contaminants. The entire assembly can then rotate such that wafer 208 is in Position B in the annealing chamber and wafer 211 is in Position A in the deposition chamber. The valves move as well such that valve 216 is now in the annealing chamber and valve 376 is in the deposition chamber.

In accordance with various embodiments, wafer 208 can be moved between deposition chamber 202 and flash heating chamber 372 using different techniques. By way of non-limiting example, wafer 208 can be coupled to a platen or other substrate support that slides between the chambers, rather than rotating between them, using a conveyor type system. An arm mechanism, aided by actuators to lift the wafer off the platen surface, can lift and move wafers between chambers in one embodiment. Additionally, as shown in FIG. 18, multiple wafers can be disposed on the substrate support such that as one or more wafers are receiving precursors for deposition, one or more additional wafers undergo flash heating. Areas for cooling can be placed between the chambers in one embodiment so as one or more wafers undergo deposition in a deposition chamber, one or more wafers undergo annealing in a heating chamber, and one or more wafers undergo cooling in a cooling chamber, for example. The various chambers can be spaced apart in a circular manner so as the wafers rotate, they move from chamber to chamber. In one embodiment, multiple deposition and/or heating chambers are used.

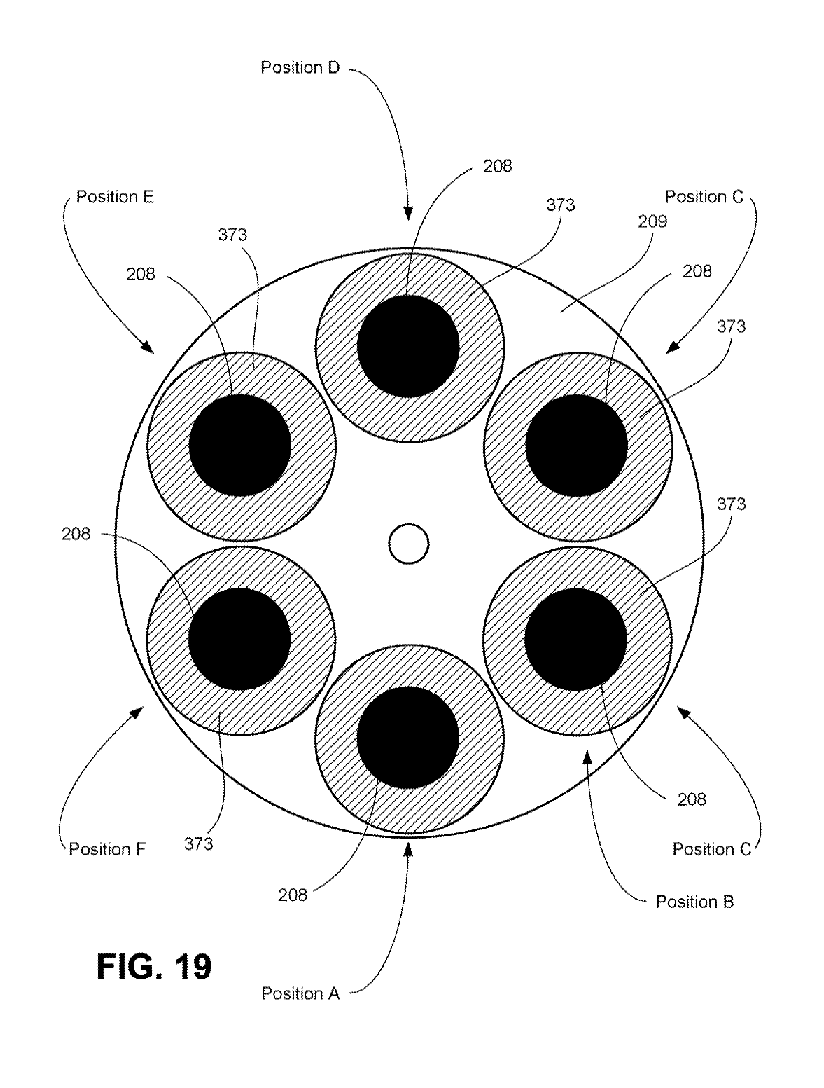

FIG. 19 depicts another embodiment of platen 209 including a plurality of wafers 208. Each wafer 208 is positioned in the middle of a shutter 373 to allow gases and contaminants to be purged from the appropriate chamber at the appropriate times. Shutters 373 can align with valves 216 and 376 when in the deposition and annealing chamber, respectively, to facilitate purging. In one embodiment, deposition system 370 includes a plurality of deposition and/or annealing chambers. For example, position A and position B can represent locations within the deposition chamber and annealing chamber as previously described. Position C could correspond to a location within a second deposition chamber, Position D a second annealing chamber, position E a third deposition chamber, and position F a third annealing chamber. As one wafer 208 undergoes deposition at Position A, another undergoes deposition at Position C and another at Position E. Simultaneously, other wafers are each undergoing annealing at Positions B, D, and F. In one embodiment, one or more of the positions could be cooling stations. For example, Position C could be a first cooling station after one deposition cycle at Position A and one annealing cycle at Position B. Position F could be a second cooling station after another deposition cycle at Position D and another annealing cycle at Position E. Other configurations can be used. For example, cooling stations could be used in between deposition and annealing.

In other embodiments, wafer 208 can remain stationary within deposition chamber 202 and the heat source 374 moved in and out of the deposition chamber to flash heat the substrate surface after every or every few deposition cycles. Accordingly, a flash heating chamber may not be needed. In yet another embodiment, flash heat source 374 can be incorporated into deposition chamber 202.

In accordance with embodiments, various pressure gradients and/or sealing mechanisms can be established within flash heating chamber 372 and deposition chamber 202 to minimize the incorporation of contaminants into the substrate surface. For example, in one embodiment the two chambers are physically open to one another, as illustrated in FIG. 16. Deposition chamber 202 can be kept at a more positive pressure relative to flash heating chamber 372 to minimize any flow of contaminants from heating chamber 372 to deposition chamber 202. In one embodiment, the positive pressure from deposition chamber 202 to heating chamber 372 is maintained by only introducing precursor materials into deposition chamber 202 and only removing or purging leftover precursors, byproducts and other potential contaminants from heating chamber 372. For example, only valve(s) 376 could be used to remove gases from the system such that a positive pressure flow is maintained from the deposition chamber to the heating chamber. In another embodiment, heating chamber 372 and deposition system 202 are sealed with respect to one another using a door or plate that can open to allow wafer 208 and/or flash heat source 374 to move between the two chambers.

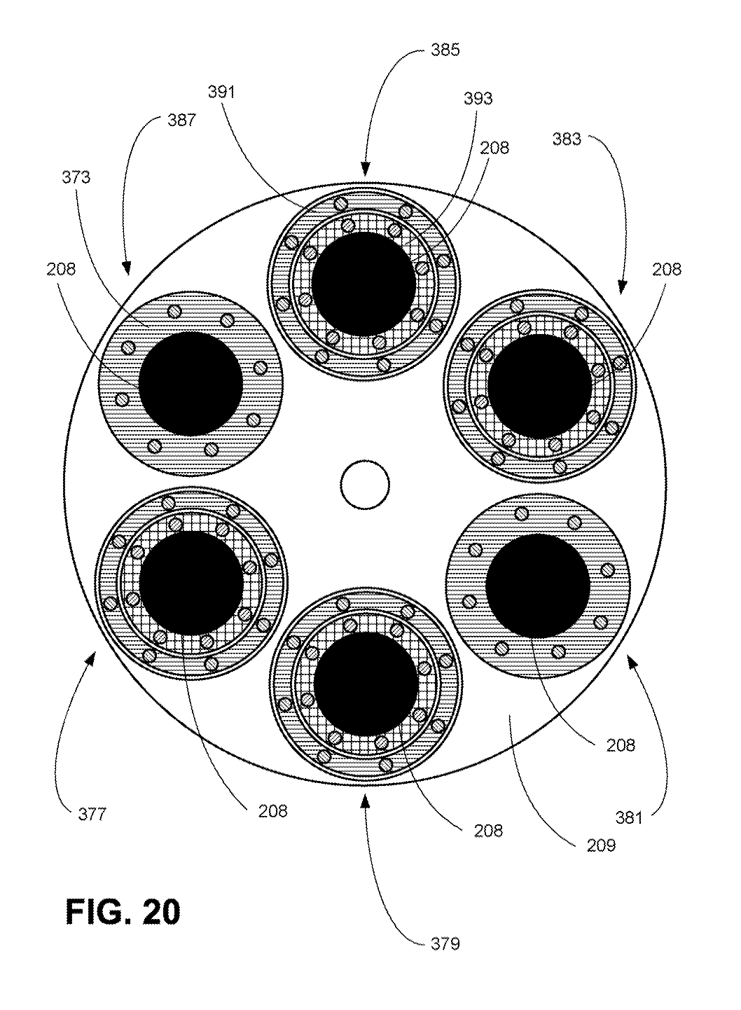

FIG. 20 depicts another embodiment of platen 209 including a plurality of wafers 208 positioned thereon for deposition and annealing. In the embodiment of FIG. 20, platen 109 is made of a mesh or thin wire like material as previously described. Wafers 208 are placed atop platen 209. A plurality of static stations 377, 379, 381, 383, 385, and 387 are provided. These stations do not move. As platen 209 rotates, it carries each wafer from one station to the next. Platen 209 is depicted transparently to illustrate the underlying valve structure. For example, ring 391 at station 385 can be a ring of a first valve feeding to a first pump as shown by reference 273 in FIG. 8. Ring 393 can be a ring of a second valve leading to a second pump. The valves corresponding to these rings are stationary and located beneath platen 209. Platen 209 and wafers 208 rotate above the valves and rings while the valves and rings remain stationary.

Stations 377, 379, 383, and 388 can be stations in individual deposition chambers. The two ring mechanism can provide better purging abilities as described with respect to FIGS. 7 and 8. Each station will have two valves and two pumps. One corresponding to each of the rings. Stations 381 and 387 can be stations in separate annealing chambers. These stations only include a single ring 379 and valve mechanism although other embodiments may include multiple ring structures here as well. During one complete rotation of platen 209, each wafer will undergo four deposition cycles and two annealing cycles.

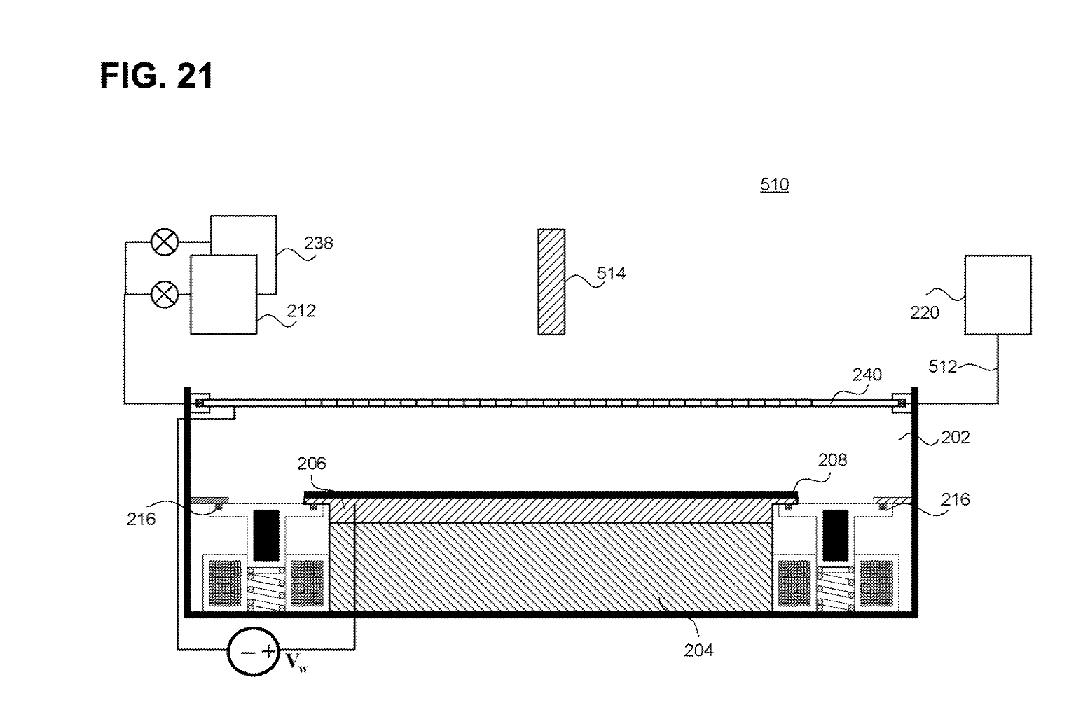

FIG. 21 depicts a deposition system 510 in accordance with another embodiment including a heat source for annealing. System 510 includes a heat source configured to flash heat the substrate surface without utilizing a separate heating chamber. Plasma generation chamber 220 is configured away from the upper surface of deposition chamber 202. Plasma chamber 220 is remotely connected to the deposition chamber 202 through ducts 512. Radicals from chamber 220 are delivered to chamber 202 through separation plate 240 which acts as a showerhead. A flash lamp or laser 514 is positioned above the deposition chamber. Separation plate 240 can be formed of quartz in FIG. 21. By forming the separation plate of quartz, light and heat energy can pass from source 514 into the deposition chamber. In one embodiment, valves are not used in separation plate 240. Orifices can be used in place of valves and the first precursor, radical second precursor, and purge gas controlled through valves remote from plate 240. By using quartz for plate 240, movement of the laser(s) (or other heat source(s)) and/or substrate can be avoided while still reaching all portions of the substrate surface. The various deposition systems previously described can also be formed using quartz plates as described.

In one embodiment, heat source 514 is a laser. Laser 514 can be tuned to a specific wavelength for exciting known contaminants or heating known materials deposited on the substrate surface. In one embodiment, laser 514 moves relative to deposition chamber 202. Laser 514 can move or scan the surface of the wafer to ensure that all portions of the substrate are properly heated. The laser can move to reach those portions obscured with the laser in a different position. For example, the laser can dynamically move as the beam scans the surface in order to avoid the beam's path crossing the ducts, port holes, and/or valves of the showerhead. In one embodiment, the laser's beam can be moved using one or more moveable mirrors. In one embodiment, multiple lasers are used for source 514. The multiple lasers may extend across the diameter of a wafer to more quickly heat the substrate and/or avoid temperature gradients. In one embodiment, a fluid is placed in plate 240 or pumped through plate 240 to cool it as the laser passes through. In one embodiment, the fluid is chosen so as to not refract or obstruct laser 514.

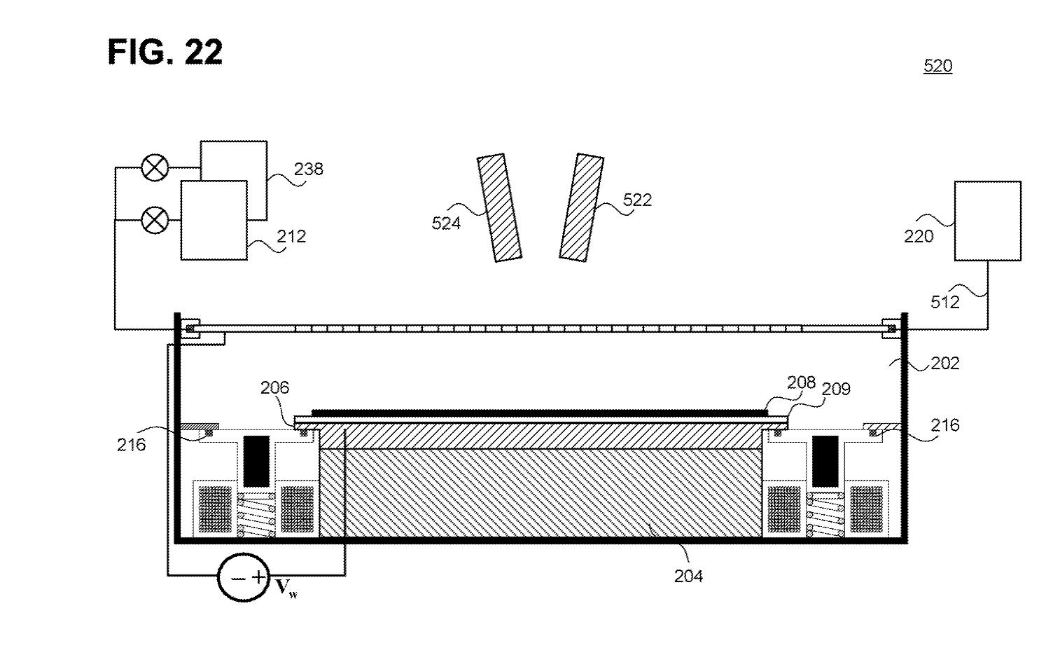

In one embodiment, two lasers 524 and 522 are used as shown in the deposition system 520 of FIG. 22. Laser 522 is positioned at a first angle with respect to the substrate to effectively reach a first portion of the substrate surface. Laser 524 is positioned at a second angle with respect to the substrate to effectively reach a second portion of the substrate surface. For example, laser 522 can reach certain portions of the substrate reachable through the ducts in plate 240 when positioned at the first angle. Laser 524 can reach certain portions of the substrate reachable between ducts in plate 240 when positioned at the second angle. In one embodiment, laser 524 and/or 522 are scanned across the wafer's surface while dynamically moving to avoid their beam's crossing the ducts, etc. of showerhead 240. In one embodiment, laser 522 includes a plurality of lasers extending across the diameter of the substrate and laser 524 includes a plurality of lasers extending across the diameter of the substrate. Each of the lasers of 522 and 524 can respectively be positioned at or about the same angle. The substrate or lasers can be moved to reach every portion of the substrate surface.

In one embodiment, one or more lasers are tuned to an absorption coefficient associated with particular materials or layers formed on the substrate. If annealing is performed with a known first material deposited, the lasers can be tuned in wavelength to the absorption coefficient of that first material for efficient heating and annealing. If several different materials are deposited and need to be heated, a single laser can be tuned to various wavelengths to properly heat each of these materials. The laser wavelength can be modulated at these various wavelengths as it passes over the substrate surface to effectively heat each portion, regardless of material. In one embodiment, multiple lasers can be used to accomplish the various laser wavelengths. A first laser 522 could be tuned to one wavelength and a second laser 524 tuned to another. The various lasers can be alternately powered to heat each portion of the surface using each wavelength as the lasers pass over the substrate or the substrate passes under the lasers. In another embodiment, each laser continuously emits at its selected wavelength.

ALD of a Non-Volatile Storage Element

Although the aforementioned systems and methods can be used to deposit any type of film, including but not limited to, barrier layers, adhesion layers, seed layers, low dielectric constant films, high dielectric constant films, and other conductive, semi-conductive, and non-conductive materials on any type of substrate, in one embodiment, one or more of these systems and methods are used to deposit one or more layers of a non-volatile semiconductor storage element that utilizes a high-K dielectric and inter-gate programming.

As non-volatile storage device dimensions decrease, the channel size is reduced which leads to a need for increased capacitive coupling between the channel and the floating gate in order to maintain the gate's influence over the channel. One way to achieve this is to reduce the effective thickness of the dielectric region between the channel and the floating gate. A high-K material can meet this need because the high-K material will have an effective thickness that is lower than its actual thickness such that it can be used with a smaller channel size.

In order to provide a high-K channel dielectric, a suitable growth or deposition process must be employed to ensure a high-quality material having the necessary properties to maintain control over the channel. A low thermal budget process in accordance with one embodiment employing one or more of the systems and methods described with respect to FIGS. 2-22 can be used to deposit such a high quality high-K dielectric material. In accordance with one embodiment, an ALD process incorporating one or more of the systems and methods described herein is capable of depositing a high-K material for a device that utilizes inter-gate programming while minimizing or eliminating the poly-crystallization of the high-K material and the inter-diffusion of silicon atoms into the high-K material and/or metal atoms into silicon or poly-silicon.

A distinct feature of one film deposited in accordance with one embodiment, is the ability to simultaneously grow one or more additional layers such as SiO₂ and SiON while depositing a desired layer. Although this may not be desired in some instances due to the higher band gap energy (ΔE_{c}) of the interfacial layers, in other instances as hereinafter described with respect to various embodiments including high-K channel dielectrics and inter-gate programming, it may prove to be a considerable benefit as hereinafter described.

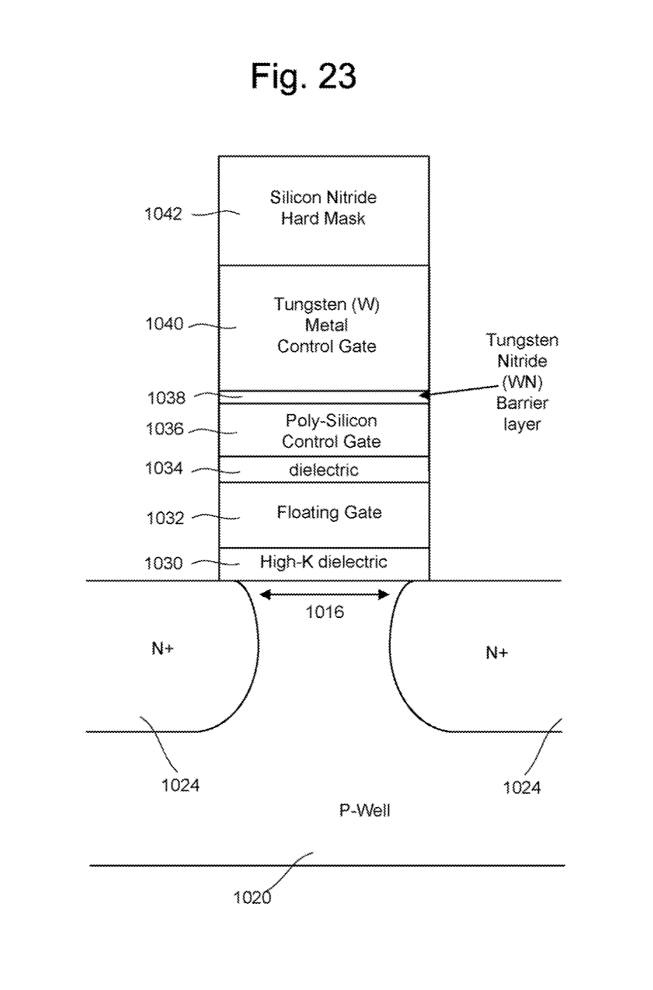

FIG. 23 is a two-dimensional block diagram of one embodiment of a flash memory cell according to the present invention that utilizes inter-gate programming and a high-K channel dielectric. Although a flash memory cell is discussed, other types of non-volatile memory can also be used in accordance with the present invention. The memory cell of FIG. 23 includes a triple well comprising a P substrate, a N-well and a P-well 1020. The P substrate and the N-well are not depicted in FIG. 23 in order to simplify the drawing. Within P-well 1020 are N+ diffusion regions 1024, which serve as source/drains. Whether N+ diffusion regions 1024 are labeled as source regions or drain regions is somewhat arbitrary; therefore, the N+ diffusion source/drain regions 1024 can be thought of as source regions, drain regions, or both.

Between N+ diffusion regions 1024 is the channel 1016. Above channel 1016 is dielectric area 1030, often referred to as a channel dielectric. Above dielectric area 1030 is floating gate 1032. The floating gate, under low voltage operating conditions associated with read or bypass operations, is electrically insulated/isolated from channel 1016 by dielectric area 1030. Above floating gate 1032 is dielectric area 1034, often referred to as an inter-gate dialectic. Above dielectric area 1034 is a poly-silicon layer of control gate 1036. Above poly-silicon layer 36 is a conductive barrier layer 1038 made of Tungsten Nitride (WN). Above barrier layer 1038 is a low resistivity metal gate layer 1040 made of Tungtsen. WN layer 1038 is used to reduce the inter-diffusion of Tungsten into the poly-silicon layer of control gate 1036, and also of silicon into Tungsten layer 1040. Note that, in one embodiment, control gate 1036 consists of layers 1036, 1038, and 1040 as they combine to form one electrode. In other embodiments, a single metal layer, or multiple metal layers without using a poly control gate sub-layer 1036 can be used. Dielectric 1030, floating gate 1032, dielectric 1034, poly-silicon layer of control gate 1036, WN layer 1038 of control gate, and Tungsten metal layer 1040 of control gate comprise a stack. An array of memory cells will have many such stacks.

Various sizes and materials can be used when implementing the memory cell of FIG. 23. In one embodiment, dielectric 1030 is 14 nm and includes a high-K material. In other embodiments, dielectric 1030 can be 8 nm-15 nm. Examples of high-K materials that can be used in dielectric 1030 include Aluminum Oxide Al₂O₃, Hafnium Oxide HfO₂, Hafnium Silicate HfSiO_{X}, Zirconium Oxide, or laminates and/or alloys of these materials. Other high-K materials can also be used.

Use of high-K dielectric materials between the crystalline silicon channel, and a poly gate typically creates two interfacial layers above and below the high-K material itself. These interfacial layers are composed of SiO₂, or Silicon Oxy-nitride (SiON), with some fraction of metal atoms that may have diffused from the high-K material itself. These interfacial layers are usually formed naturally and not intentionally, and in many applications these interfacial layers are undesirable, as their dielectric constant tends to be substantially lower than the dielectric constant of the high-K material. In the present application, because the high-K dielectric is substantially thicker than that used for gate dielectrics of advanced MOS logic transistors, an interfacial layer that is 1 nm thick or even thicker may not only be tolerable, but also a welcome feature. This will especially be the case if the lower K interfacial layer provides higher mobility for channel electrons, and/or higher immunity to leakage currents because of the higher energy barrier (bottom of the conduction band offset) that the interfacial layer may offer. Higher energy barriers reduce the possibility of electron injection into the high-K dielectric by both direct tunneling, and Fowler-Nordheim (FN) tunneling. Silicon nitride or other inter-diffusion barrier insulators and oxygen diffusion barrier insulators may also be deposited or grown at the interface of silicon and high-K material in order to impede inter-diffusion of various atoms across material boundaries and/or impede further growth of interfacial silicon oxide layers. Toward these ends, in some embodiments, layers of silicon oxide and/or silicon nitride may be intentionally grown and/or deposited to form part of the interfacial layers above and/or below the high-K dielectric(s).

Floating gate 1032 is 20 nm and is typically made from poly-silicon that is degenerately doped with n-type dopants in one embodiment; however, other conducting materials, such as metals, can also be used. Dielectric 1034 is 10 nm and is made of SiO₂; however, other dielectric materials can also be used. Control gate sub layer 1036 is 20 nm and is made from poly-silicon in one embodiment; however, other materials can also be used. The WN conducting diffusion barrier layer 1038 is 4 nm thick. Tungsten metal control gate layer 1040 is 40 nm thick. Other sizes for the above described components can also be implemented. Additionally, other suitable materials, such as replacing W/WN with Cobalt Silicide, can also be used. The floating gate and the control gate can also be composed of one or more layers of poly-silicon, Tungsten, Titanium, or other metals or semiconductors.

As mentioned above, dielectric 1030 includes a high-K material. A “high-K material” is a dielectric material with a dielectric constant K greater than the dielectric constant of silicon dioxide. The dielectric constant K of silicon dioxide is in the range 3.9 to 4.2. For the same actual thickness, a high-K material will provide more capacitance per unit area than silicon dioxide (used for typical dielectric regions). In the discussion above, it was stated that as channel size becomes smaller, the thickness of the dielectric region between the channel and the floating gate should be reduced. What is learned is that it is the effective thickness that must be reduced because it is the effective thickness that determines the control of the floating gate over the channel. Effective thickness is determined as follows:

$$EffectiveThickness = \frac{ActualThickness}{\frac{actualK}{SiliconDioxideK}}$$

where Actual Thickness is the physical thickness of the dielectric region, actualK is the dielectric constant for the material used in the dielectric region and SiliconDioxideK is the dielectric constant for SiO₂.

A high-K material will have an effective thickness that is lower than its actual thickness. Therefore, a high-K material can be used with a smaller channel size. The smaller effective thickness accommodates the smaller channel size, allowing the gate to maintain the appropriate influence over the channel. The larger actual thickness of a high-K material helps prevent the leakage discussed above.

In one embodiment, the programming and erasing is performed by transferring charge between floating gate 1032 and control gate 1036, across dielectric 1034. This is advantageous because the programming mechanism (e.g. tunneling) is now not so burdened with strong coupling. Rather, the strong steering function is placed between the floating gate and the channel, matching the strong channel coupling dictate for scaled channels. Thus, the memory cell of FIG. 23 has interchanged dielectric roles. Namely, a high-K dielectric and associated steering function placed between floating gate 1032 and channel 1016, and non-scaled down tunnel oxide (e.g. ˜>85 Å, targeted towards high reliability, minimal leakage current) between control gate 1036 and floating gate 1032. Thus, in some embodiments, dielectric 1034 serves as the tunnel oxide.

Some advantages which may be realized with some embodiments of the above described memory cell includes the ability to properly scale the device; wear associated with program/erase can be confined to the inter-gate region (away from the channel), which can increase endurance; lower program/erase voltages and/or higher reliability by using thicker dielectrics; and the elimination of the need to aggressively scale tunnel oxide of traditional NAND (or flash memories with other architectures such as NOR). A designer of a memory cell according to the present invention should be mindful of GIDL and a lower control gate coupling ratio (less Q_{fg}, stronger magnification of channel noise and larger manifestations of cell-to-cell variations).

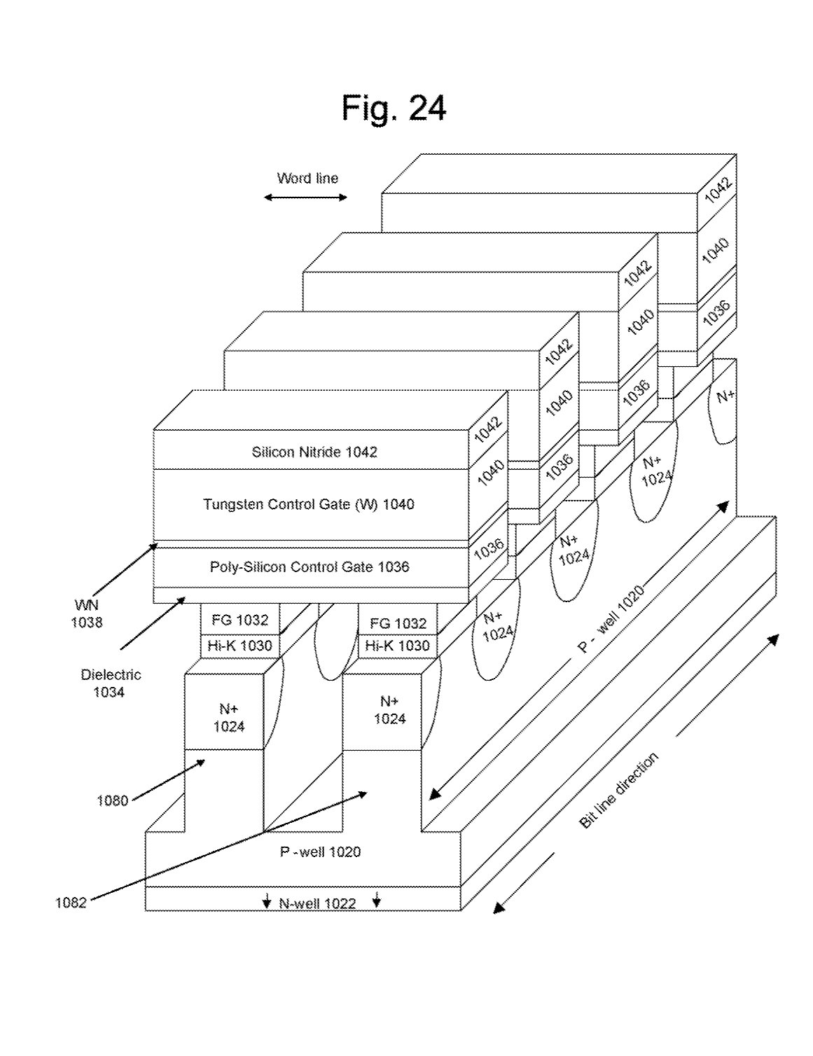

In one embodiment, the memory cell of FIG. 23 is a NAND type flash memory cell. In other embodiments, other types of flash memory cells can be used. FIG. 24 is a three dimensional drawing of two NAND strings 1080 and 1082 according to one embodiment of the present invention. FIG. 24 depicts four memory cells on strings 1080 and 1082; however, more or less than four memory cells can be used. For example, typical NAND strings consist of 16, 32 or 64 NAND cells in series. Other sizes of NAND strings can also be used. Each of the memory cells has a stack as described above with respect to FIG. 23. FIG. 24 further depicts N-well 1022 below P-well 1020, the bit line direction along the NAND string and the word line direction perpendicular to the NAND string. The P-type substrate below the N-well is not shown in FIG. 24. In one embodiment, the control gates form the word lines. In another embodiment, the control gate poly-silicon layer 1036, WN layer 1038 and Tungsten layer 1040 form the word lines or control gates. In many embodiments, a Silicon Nitiride layer 1042 is above the Tungsten layer 1040, and serves as a hard mask for etching the multiple gate stacks to form individual word lines. Another purpose of the nitride (or other material) hard mask is to provide a thickening of the spacers that are formed on the side walls of the stacks by moving the thinning regions of the spacers further away from the control conducting word lines and placing the thinning portions of the spacers vis-à-vis the nitride hard mask residing on top of the upper-most control gate sub-layer.

The memory cells of FIGS. 23-24 are programmed by transferring charge from the floating gate to the control gate. In one embodiment, electrons will tunnel from the floating gate to the control gate via Fowler-Nordheim tunneling. In other embodiments, other mechanisms can be used.

The memory cells described in FIGS. 23-24 are to be distinguished in their program and erase characteristics from that of prior art NAND devices. In prior art devices the control gate attempts to tightly couple to the floating gate and control its potential with respect to the substrate, causing electrons to tunnel from floating gate to substrate when the floating gate is sufficiently negative with respect to the substrate (erase; control gate held at ground, substrate raised to high voltage), or to tunnel from the substrate to the floating gate when the floating gate is sufficiently positive with respect to the substrate (program; substrate held at ground, control gate raised to a variable high voltage). Since the substrate is in common with many memory cells, it is convenient to apply a high fixed voltage to it, but it is not convenient to apply a variable low or negative voltage to a common word line connecting multiple control gates, and thereby selectively control the degree of electron removal from these different cells. Thus, the “erase” condition is used to refer to removal of substantially “all” electrons from a collection of cells, setting all of them to a common low threshold state, typically a negative value. The erase of multiple cells is then followed by a variable program cycle that can be terminated on a cell by cell basis to set each cell to a unique state while continuing to program other cells on the same word line to a different state, as described earlier.

In the devices of FIGS. 23-24, the substrate is tightly coupled to the floating gate via the high dielectric constant material and the control gate is relatively weakly coupled to the floating gate so that reversing the polarity of the definition of erase and program is convenient. That is, when the substrate is raised to a high potential, the floating gate is also raised to a relatively high potential, and many electrons are transferred to the floating gate by tunneling from a grounded control gate, resulting in the collection of cells having a high threshold as viewed from the control gate. Programming, or setting a variable threshold to represent the data state, is accomplished by selectively removing some electrons by raising the control gate in a controlled fashion and terminating the electron removal on a cell by cell basis. This results in selectively reducing the threshold voltage as seen from the control gate, in direct contrast to the prior art devices.

In one example of programming a memory cell as depicted in Figures. 23-24, the drain and the p-well will receive 0 volts while the control gate receives a set of programming pulses with increasing magnitudes. In one embodiment, the magnitudes of the pulses range from 7 volts to 15 volts. In other embodiments, the range of pulses can be different. During programming of a memory cell, verify operations are carried out in the periods between the pulses. That is, the programming level of each cell of a group of cells being programmed in parallel is read between each programming pulse to determine whether it is equal to or greater than a verify level to which it is being programmed. One means of verifying the programming is to test conduction at a specific compare point. The cells that are verified to be sufficiently programmed are locked out, for example in NAND cells, by pre-charging the bit line voltage from 0 to Vdd (e.g., 2.5 volts) to stop the programming process for those cells. In some cases, the number of pulses will be limited (e.g. 20 pulses) and if a given memory cell is not completely programmed by the last pulse, then an error is assumed. In some implementations, memory cells are erased (in blocks or other units) prior to programming.

One means for verifying is to apply a pulse at the word line corresponding to the target threshold value and determine whether the memory cell turns on. If so, the memory cell has reached its target threshold voltage value. For arrays of flash memory cells, many cells are verified in parallel. For some embodiments of multi-state flash memory cells, after every individual program pulse the memory cells will experience a set of verification steps to determine which state the memory cell is within. For example, a multi-state memory cell capable of storing data in eight states may need to perform verify operations for seven compare points. Thus, seven verify pulses are applied in order to perform seven verify operations between two consecutive programming pulses are. Based on the seven verify operations, the system can determine the state of the memory cells. Performing seven verify operations after each programming pulse slows down the programming process. One means for reducing the time burden of verifying is to use a more efficient verify process, for example, as disclosed in U.S. patent application Ser. No. 10/314,055, “Smart Verify for Multi-State Memories,” filed Dec. 5, 2002, incorporated herein by reference in its entirety.

The memory cells of FIGS. 23-24 are erased by transferring charge from the control gate to the floating gate. For example, electrons are transferred from the control gate to the floating gate via Fowler-Nordheim tunneling. In other embodiments, other mechanisms can be used. In one embodiment, erase is performed by applying 15 volts (or another suitable level) to the p-well, floating the source/drains and applying 0 volts to the control gate.

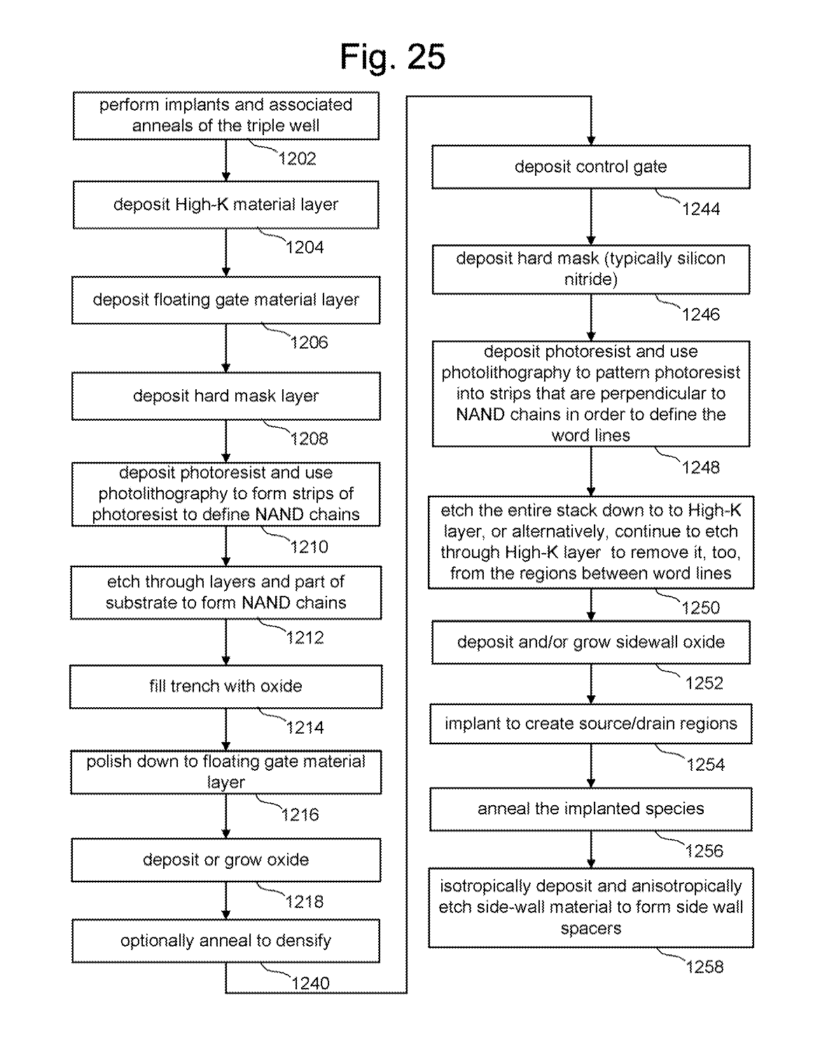

FIG. 25 is a flow chart describing one embodiment of the front end of a process for manufacturing the memory cell of FIG. 23, which covers process steps only as far as forming the sidewall spacers. This flow does not cover optional booster plates or fins, gap fill of etched volumes between the stacks, or forming contacts, metallizations, vias, and passivation. There are many ways to manufacture memory according to the present invention and, thus, the inventors contemplate that variations to that described by FIG. 25 can be used. While a flash memory chip will consist of both a peripheral circuitry, which includes a variety of low, medium, and high voltage transistors, and the core memory array, the process steps of FIG. 25 are intended only to describe in general terms one possible process recipe for the fabrication of the core memory array. Many photolithography, etch, implant, diffusion and oxidation steps that are intended for the fabrication of the peripheral transistors are omitted.

It should be noted that in flash memory chips, the convention has been to use the same floating gate oxide that is used between the floating gate and the channel for the gate oxide of low, and some medium voltage transistors in order to save extra process steps. Therefore the conventional tunnel oxide with a thickness that is usually greater than 8 nm has been limiting the performance, sub-threshold slope, and on-current drive of the low and some medium voltage transistors. This has resulted in slower program, and read characteristics. One advantage of the present invention is to provide a peripheral transistor gate oxide that is electrically and effectively much thinner than the conventional tunnel oxide, and is physically thicker than the conventional tunnel oxide. In other words, the peripheral circuitry will benefit from replacing the conventional tunnel oxide gate with high-K material(s) in alignment with the general trend of the semiconductor industry towards high-K materials.

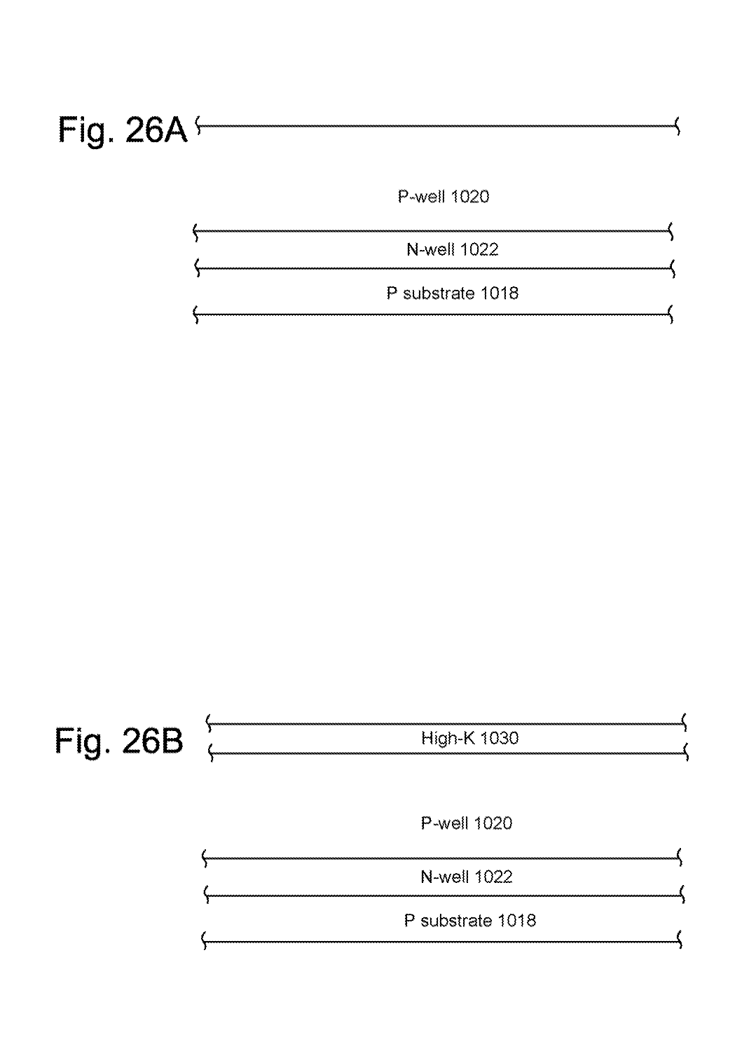

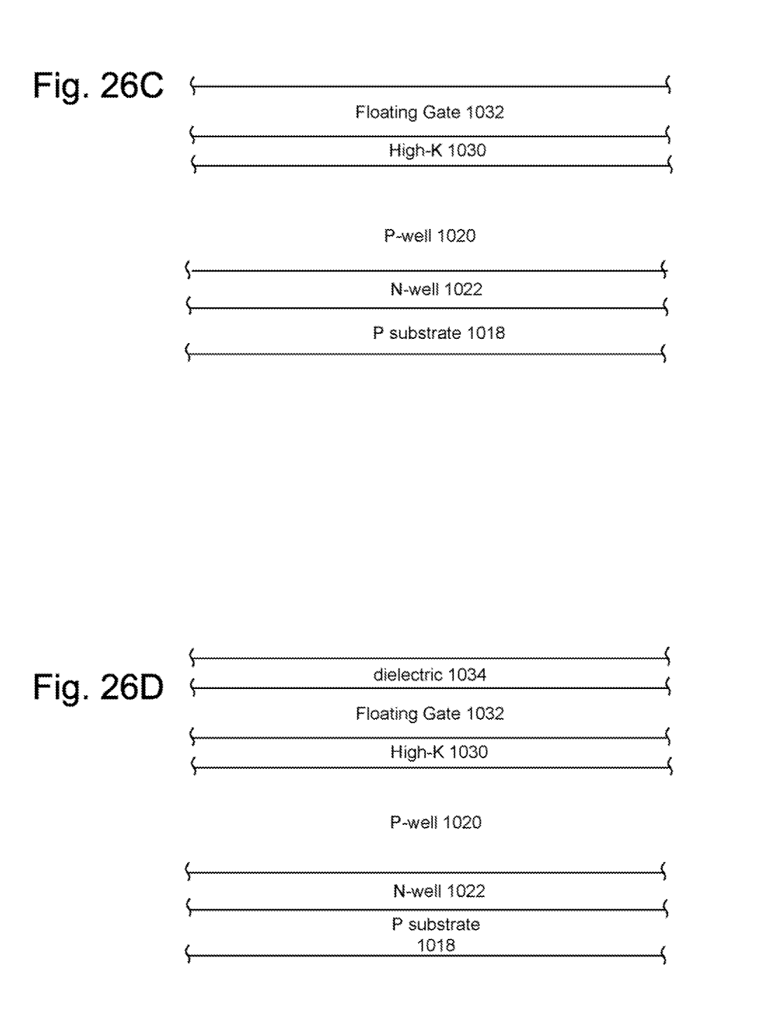

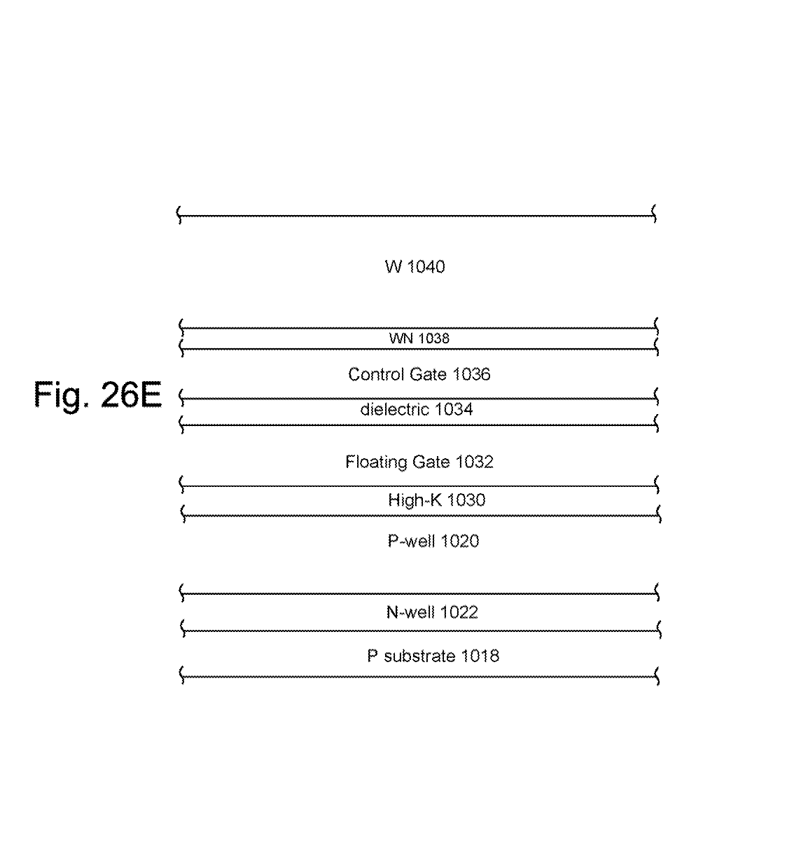

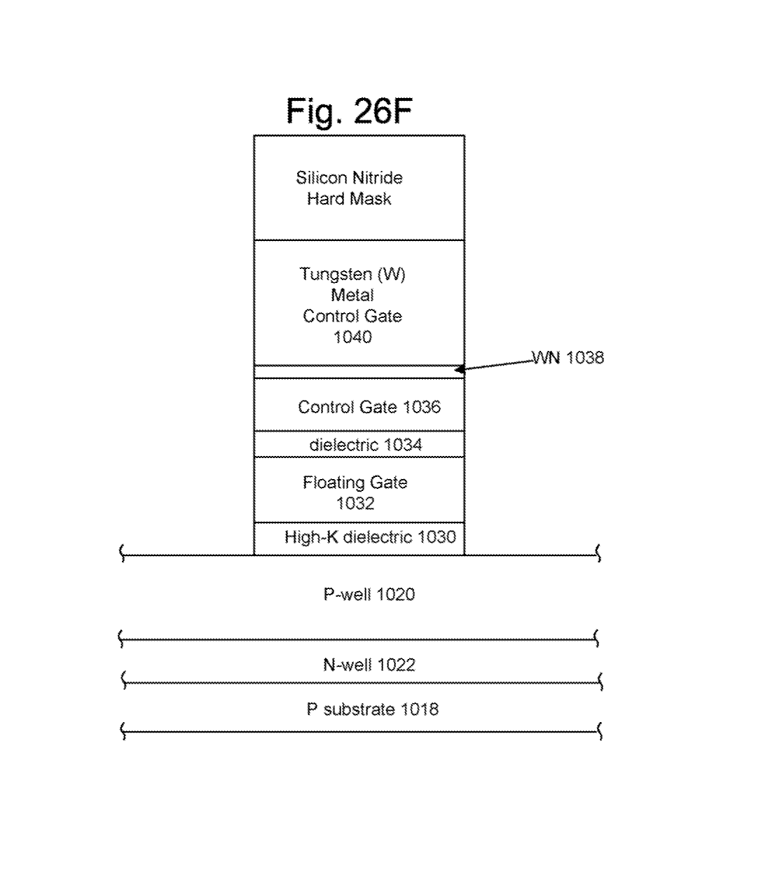

Step 1202 of FIG. 25 includes performing implants and associated anneals of the triple well. The result of step 1202 is depicted in FIG. 26A, which depicts P substrate 1018, N-well 1022 within P-substrate 1018, and P-Well 1020 within N-well 1022. The sidewalls of the N-well that isolate the P-wells from one another are not depicted. Also the N-well depth is typically much thicker than that of the P-well in contrast to FIG. 26A. The P substrate is usually the thickest consisting of the majority of the wafer thickness. In step 1204, the high-K material(s) is deposited on top of P-Well 1020. The high-K material may be deposited using Atomic Layer Deposition (ALD) in accordance with various embodiments as described herein. Additionally (and optionally), other materials may be deposited on, deposited under or incorporated within the high-K material in order to form dielectric layer 1030. The result of step 1204 is depicted in FIG. 26B, which shows dielectric layer 1030, with the high-K material. Note that one advantage of using the high-K material in the lower dielectric layer is that it can also be used for low voltage peripheral transistors to increase performance.

In accordance with one embodiment, step 1204 can include the deposition of a high-K material using one or more of the techniques as preiously described. For example, a high-density plasma deposition system can be used that utilizes a Kr feed gas in combination with a plasma chamber bias, wafer bias, selectively permeable membrane, and/or additional particle dissociating energy source to deposit an oxide, nitride, oxynitride or other suitable high-K material. In one embodiment, the high-K material can be flash heated after one or more deposition cycles to release contaminant incorporation in the substrate. As previously described, the effective thickness of the dielectric region between the channel and the floating gate should be reduced in order to maintain control of the floating gate over the channel. An ALD process incorporating Kr as an ion generating feed gas to provide high radical concentrations facilitates the deposition of a high quality dielectric having a high dielectric constant. The low thermal ALD process will minimize the diffusion of dopants, stop the poly-crystallization of the dielectric material, and minimize the inter-diffusion of silicon atoms into the material.

In accordance with various embodiments, the deposition of a high-K material at step 1204 can include the simultaneous growth of one or more interfacial layers using a high radical concentration. Interfacial layers are undesirable in typical applications, as previously discussed, given that their dielectric constant tends to be substantially lower than the dielectric constant of the high-K material. In accordance with various embodiments of the present invention, however, these interfacial layers can be beneficial, and hence, a high radical concentration is achieved to facilitate the growth of lower dielectric constant interfacial layers while performing a deposition process. While a grown interfacial layer such as SiO₂ may have a lower dielectric constant, it also has a higher energy barrier (ΔE_{c}), that reduces the possibility of electron injection into the high-K dielectric by both direct tunneling and Fowler-Nordheim tunneling. Because a storage element in accordance with embodiments is programmed by transferring a charge from the control gate across the inter poly dielectric to the floating gate, a barrier to tunneling from the channel is very beneficial. This is in contrast to typical storage elements where tunneling across the dielectric layer separating the channel from the floating gate is achieved to program and erase the cell.

A high-density plasma source chamber utilizing one or more techniques as previously described can be used in one embodiment to increase the radical concentration delivered to the reacting surface for deposition. Some of the highly reactive radicals (e.g., oxygen) can penetrate the high-K dielectric being deposited and react with the underlying silicon substrate to grow one or more interfacial layers. These interfacial layers are grown in addition to the material being deposited. For example, an Al₂O₃ high-K material may be deposited while one or more lower-K SiO₂ interfacial layers are grown from the silicon based substrate. After the Al containing first precursor is introduced, adsorbed, and purged from the deposition chamber, oxygen radicals can be generated from a high-density plasma source and introduced to the deposition chamber, along with Kr ions, to react at the substrate surface and form a monolayer of Al2O3. Some of the oxygen radicals will reach the silicon substrate and cause the growth of SiO₂.

The aforementioned simultaneous growth and deposition technique can be used when depositing any film where it is desired o produce such interfacial layers. The technique need not be practiced in conjunction with the storage cell presented herein.

In step 1206, the floating gate is deposited over dielectric layer 1030 using CVD, PVD, ALD or another suitable method. In one embodiment, an ALD process including one or more of the techniques as heretofore described is used to deposit the floating gate. The result of step 1202 is depicted in FIG. 26C, which shows floating gate layer 1032 deposited on top of high-K dielectric layer 1030.

Step 1208 of FIG. 25 includes depositing a hard mask using, for example, ALD, PVD, or CVD to deposit SiO₂ or Si₃N₄. Again, one or more processes in accordance with embodiments previously described can be used at step 1208. In step 1210, photolithography is used to form strips of photoresist over what will become the NAND chains. Step 1212 includes etching through all layers, including part of the substrate. First, the hard mask is etched through using anisotropic plasma etching, (i.e. reactive ion etching with the proper balance between physical and chemical etching for each planar layer encountered). After the hard mask layer is etched into strips, the photoresist can be stripped away and the hard mask layer can be used as the mask for etching the underlying layers. The process, then includes etching through the floating gate material, the high-K dielectric material and approximately 0.1 micron into the substrate to create trenches between the NAND strings, where the bottom of the trenches are inside the top P-well 1020. In step 1214, the trenches are filled with SiO₂ (or another suitable material) up to the top of the hard mask using CVD, rapid ALD or PSZ STI fill as described in “Void Free and Low Stress Shallow Trench Isolation Technology using P-SOG for sub 0.1 Device” by Jin-Hwa Heo, et. al. in 2002 Symposium on VLSI Technology Digest of Technical Papers, Session 14-1. PSZ STI fill is Polysilazane Shallow trench isolation fill The fill sequence includes spin coat by coater, and density by furnace. Si—N bond conversion to Si—O bond enables less shrinkage than conventional SOG (Spin On Glass). Steam oxidation is effective for efficient conversion. One proposal is to use Spin-On-Glass (SOG) for the dielectric layer, which is called polysilazane-based SOG (SZ-SOG), a material used in integrating the inter layer dielectric (ILD) applications because of its excellent gap filling and planarization properties, and thermal oxide like film qualities.

In step 1216 Chemical Mechanical Polishing (CMP), or another suitable process, is used to polish the material flat until reaching the floating gate poly-silicon. The floating gate is polished to 20 nm (10-100 nm in other embodiments). In step 1218, the inter-poly tunnel dielectric (e.g. dielectric 34) is grown or deposited using ALD, CVD, PVD, Jet Vapor Deposition (JVD) or another suitable process. One or more ALD processes in accordance with various embodiments as previously described can be used at step 1218 to deposit the inter-poly tunnel dielectric. FIG. 26D, which shows the inter-poly dielectric region 1034 over floating gate 1032, depicts the device after step 1218. Examples of materials that can be used for the inter-poly tunnel dielectric include (but are not limited to) SiO₂, Si₃N₄, an alloy with a varying mole fraction as a function of depth, an alloy or nano-laminate of aluminum oxide and silicon oxide, an alloy or nano-laminate of silicon nitride and silicon oxide, an alloy or nano-laminate of silicon oxide and hafnium oxide, an alloy or nano-laminate of aluminum oxide and hafnium oxide, or other suitable materials.

In one embodiment, the inter-poly tunnel oxide layer can be created in the manner disclosed by “Resonant Fowler-Nordheim Tunneling through Layered Tunnel Barriers and its Possible Applications,” Alexander Korotkov and Konstantin Likharev, 1999 IEEE, 0-7803-5413-3/99 (hereinafter “Likharev I”); “Riding the Crest of a New Wave in Memory, NOVORAM: A new Concept for Fast, Bit-Addressable Nonvolatile Memory Based on Crested Barriers,” Konstantin and Likharev, Circuits and Devices, July 2000, p. 17 (hereinafter “Likharev II”); or U.S. Pat. No. 6,121,654 granted Sep. 19, 2000 titled: “Memory device having a crested tunnel barrier” all of which are incorporated herein by reference in their entirety. The oxide layer bottom of the conduction band energy diagram can be rounded near the mid-depth region of the tunnel dielectric, instead of forming a sharp triangle as in FIG. 3a of U.S. Pat. No. 6,121,654, which is incorporated herein by reference in its entirety, by varying the mole fraction of binary oxides such as (HfO₂)ₓ(Al₂O₃)₁₋ₓ Atomic layer deposition (ALD) can be employed to deposit mixed multiple dielectrics (e.g. (HfO₂)ₓ(Al₂O₃)₁₋ₓ) (see “Energy gap and band alignment for—(HfO₂)ₓ(Al₂O₃)₁₋ₓ on—100-Si” by H. Y. Yu et. al. Applied Physics Letters Volume 81, Number 28, July 2002 (“hereinafter “Yu”)), whose mole fraction, x, gradually changes with depth into the oxide in order to create crested barriers (see Likharev I and Likharev II) that not only facilitate tunneling at lower voltages but also improve retention time and reduce disturb problems. Also Hafnium oxide and Silicon oxide, or Aluminum oxide and Silicon oxide can be paired to create crested conduction band edges. There are probably many more ALD deposited material systems composed of 2 or more materials that can have their conduction band edge energy level change in a linear or non-linear manner with changing depth in order to optimize the conduction band engineering of the tunnel dielectric. Switching of chemistry of ALD deposited tunnel barriers after every single cycle or after every few cycles of deposition can create the gradual change of mole fraction that may be conducive to constructing a tunnel dielectric that does not suffer from the issues arising from having material interfaces within the tunnel dielectric, such as trapping at mentioned interfaces.

In accordance with various embodiments, the various layers of a mixied multiple dielectric can be deposited using an atomic layer deposition process as previously described. A high-density plasma source can be used to deposit one or more varying oxide layers, for example, to form desired crested conduction band edges.

In accordance with one embodiment, however, a high-density plasma system for the deposition of an inter-poly mixed layer oxide dielectric may not be a preferred method, although it can be used. As previously described in accordance with various embodiments, a large concentration of reactive oxygen radicals can be generated to deposit high quality oxides. These radicals can penetrate a layer being deposited and grow a layer such as SiO₂ on a silicon based substrate. For example, while depositing an Al₂O₃ and/or HfO₂ oxide dielectric on top of a polysilicon floating gate, some radical oxygen will reach the polysilicon layer and cause the growth of SiO₂ interfacial layers. These low-k interfacial layers, having a large ΔE_{c}, may inhibit the transfer of electrons from the control gate to the floating gate during programming and erase operations.

In step 1240 of FIG. 25, which is an optional step, the inter-poly tunnel oxide is annealed to density the oxide, without damaging the high-K materials due to a high temperature. Note that Al₂O₃ will crystallize at approximately 800 degrees Celsius, HfO₂ will crystallize at approximately 500 degrees Celsius, HfSiOₓ will crystallize at approximately 1100 degrees Celsius, and HfSiON will crystallize at approximately 1300 degrees Celsius. In general, longer exposure times to high temperatures will result in reduced crystallization temperatures.

In one embodiment, the inter-poly tunnel oxide is flash annealed using one or more of the previously described techniques. A flash anneal in accordance with various embodiments may smooth the changing of mole fraction as well as release contaminants from the surface of the deposited material. For a crested barrier, the mole fraction x should be smaller near the interfaces and gradually peak at the middle of the barrier). After one or more deposition cycles, the surface of the inter-poly dielectric can be flash heated using one or more flash lamps or lasers to briefly raise the surface temperature of the deposited layer. This flash heating can release contaminants from the deposited layers in addition to smoothing the mole fraction. As previously described, a flash heating system can be employed to quickly remove contaminants from the surface of the material being deposited without substantially increasing the bulk wafer temperature and consequently raise processing times. The deposition chamber or flash heating chamber can be purged after the heating step to remove the released contaminants.

In step 1244, the one or more layers of the control gate are deposited on the inter-poly tunnel oxide. One or more ALD processes in accordance with embodiments as previously described can be used to deposit the control gate. In one embodiment, the materials deposited during step 1244 include poly-silicon (e.g. layer 1036), while in other embodiments this layer may be a metal layer with a proper work function, thermal stability, and etch characteristics. In some embodiments, the control gate is composed of the poly-silicon layer 1036, tungsten-nitride layer 1038, and tungsten layer 1040, all of which are deposited in step 1244. Nitride layer 1038 and tungsten layer 1040 are deposited to reduce the control gate sheet resistance and form lower resistivity word lines. These materials can be deposited in a blanket form using CVD, ALD, PVD or other suitable process. FIG. 23E, which shows poly-silicon control gate 1036, WN layer 1038 and Tungsten metal layer 1040 over inter-poly tunnel oxide 1034, depicts the device after step 1244.

On top of the Tungsten layer, a hard mask of Si₃N₄ is deposited using, for example, CVD or ALD in step 1246. One or more ALD techniques as previously described can be used at step 1246 to deposit the hard mask. In step 1248, photolithography is used to create patterns of perpendicular strips to the NAND chain, in order to etch the multi-gate stack and form word lines (i.e. control gates) that are isolated from one another. In step 1250, etching is performed using plasma etching, ion milling, ion etching that is purely physical etching, or another suitable process to etch the various layers and form the individual word lines. In one embodiment, the etching is performed until the high-K material is reached. The process attempts to leave as much high-K material as possible, but tries to etch completely through the floating gate material. In another embodiment, the process will etch all the way to the substrate. FIG. 26F, which shows the stack, depicts the device after step 1250. Note that the size of the p-well, n-well and P substrate are not necessarily drawn to scale.

In step 1252, sidewall oxidation, sidewall oxide deposition, or a combination of the two is performed. In one embodiment, sidewall oxidation using oxygen radicals generated in a high-density mixed plasma as previously described is used at step 1252. For side wall oxidation, the device is placed in a furnace at a high temperature and some fractional percentage of ambient oxygen gas, so that the exposed surfaces oxidize, which provides a protection layer. Sidewall oxidation can also be used to round the edges of the floating gate and the control gate. An alternative to high temperature (e.g. over 1000 degrees Celsius) oxide growth is low temperature (e.g. 400 degrees Celsius) oxide growth in high density Krypton plasma. More information about sidewall oxidation can be found in “New Paradigm of Silicon Technology,” Ohmi, Kotani, Hirayama and Morimoto, Proceedings of the IEEE, Vol. 89, No. 3, March 2001; “Low-Tempetrature Growth of High Silicon Oxide Films by Oxygen Radical Generated in High Density Krypton Plasma,” Hirayama, Sekine, Saito and Ohmi, Dept. of Electronic Engineering, Tohoku University, Japan, 1999 IEEE; and “Highly Reliable Ultrathin Silicon Oxide Film Formation at Low Temperature by Oxygen Radical Generated in High-Density Krypton Plasma,” Sekine, Saito, Hirayama and Ohmi, Tohoku University, Japan, 2001 IEEE; all three of which are incorporated herein by reference in their entirety.

To achieve uniform tunneling a processing step may be employed in order to make the inter-gate tunnel dielectric thicker at the edges where the field lines may be more concentrated than near the middle. Oxidation may be a suitable way of achieving this end.

In step 1254, an implant process is performed to create the N+ source/drain regions by Arsenic implantation. In one embodiment, a halo implant is also used. In step 1256, an anneal process is performed. In one embodiment, a low temperature anneal process is performed to prevent damage to the high-K material. In one embodiment, a flash anneal is performed at step 1256 in accordance with embodiments. In some embodiments, a high-K material can be used that has a high thermal budget (e.g., able to endure high temperatures without degrading). In step 1258, the process includes isotropically depositing and aniotropically etching sidewall material to form sidewall spacers.

There are many alternatives to the above described structures and processes within the spirit of the present invention. Textured gate (asperities) inter-gate tunneling is also possible, as well as Silicon-rich oxides, and graded band dielectrics. As in the existing NAND embodiment, an alternative is to fabricate the memory cells from PMOS devices with opposite polarity bias conditions for the various operations as compared to the existing NMOS implementation.

The low control gate coupling ratio will reduce the amount of floating gate charge needed to cause one volt of threshold shift as measured from the control gate as compared to existing NAND devices with its relatively high control gate coupling ratio. The benefit of this is lower programming/erase voltage levels, as compared to existing NAND. Alternatively, this advantage can be used to increase dielectric thicknesses, maintaining same program/erase voltages as in use today, but increasing overall cell reliability. Negative consequences of this are that effects of cell noise and electron charge gain or loss become amplified by the inverse of the control gate coupling ratio. These become manifest as larger shifts in threshold voltage for smaller values of control gate coupling ratio. In this respect, it is desirable not to have too small a control gate coupling ratio. A very small control gate coupling ratio will also limit the range of the amount of readable excess charge on the floating gate.

One embodiment would have a high temperature tolerant channel dielectric, such as Haffiium Silicate or Aluminum Oxide. A relatively thin poly-silicon floating gate, a suitable inter-gate dielectric, and a word line consisting of poly-silicon, covered by Tungsten Nitride, followed by Tungsten, constitute an embodiment that does not have to resort to a Damascene process. However, if poly-crystallization of amorphous-as-deposited silicon floating gate is to be avoided, then a low thermal budget process may have to be adopted that may include the Damascene process. An amorphous floating gate may offer a better quality tunneling oxide grown or deposited there upon.

Silicon Nitride has been proposed as a tunneling material for flash memories. A Damascene process can be employed to implant and anneal the source/drain junction of the memory array before the stack gates or some layers of the stack are deposited. Some materials such as Hafnium Oxide tend to crystallize at moderately high processing temperatures, which can lead to leakage currents at grain boundaries. To avoid crystallization a Damascene process avoiding such high temperature exposure post high-K dielectric deposition can be adopted.

The foregoing description of embodiments of the present invention has been provided for the purposes of illustration and description. It is not intended to be exhaustive or to limit the invention to the precise forms disclosed. Many modifications and variations will be apparent to the practitioner skilled in the art. Embodiments were chosen and described in order to best describe the principles of the invention and its practical application, thereby enabling others skilled in the art to understand the invention, the various embodiments and with various modifications that are suited to the particular use contemplated. It is intended that the scope of the invention be defined by the following claims and their equivalents.

What is claimed is:

1. A method of depositing a film, comprising:
depositing one or more layers of said film onto a substrate during a number of deposition cycles, wherein each of said deposition cycles includes introducing a first precursor to said substrate and introducing a second precursor to said substrate; and
flash heating a surface of said film after a predetermined number of said deposition cycles to release contaminants from said film, said flash heating includes raising a temperature of said surface of said film without substantially raising a temperature of a bulk of said substrate.

2. The method of claim 1, wherein:
said step of flash heating includes raising said temperature of said surface of said film at a rate of 10⁶ degrees Celsius per second.

3. The method of claim 1, wherein:
said step of flash heating includes raising said temperature of said surface of said film at a rate of more than 300 degrees Celsius per second.

4. The method of claim 1, wherein:
said step of flash heating includes raising said temperature of said surface of said film at a rate of more than 350 degrees Celsius per second.

5. The method of claim 1, wherein:
said step of flash heating includes flash heating said surface of said film with at least one flash lamp.

6. The method of claim 1, wherein:
said step of flash heating includes flash heating said surface of said film with at least one laser.

7. The method of claim 6, wherein:
said flash heating includes moving said substrate to expose substantially all of said surface of said film to said at least one laser.

8. The method of claim 6, wherein:
said flash heating includes moving said laser to expose substantially all of said surface of said film to said at least one laser.

9. The method of claim 6, wherein flash heating with said at least one laser includes:
providing said at least one laser at a location outside of a deposition chamber having an upper surface formed of quartz;
passing one or more beams of said at least one laser through said quartz upper surface to flash heat said surface of said film.

10. The method of claim 6, wherein flash heating with said at least one laser includes:
providing a first laser having a beam tuned to a particular frequency associated with one or materials of said film.

11. The method of claim 10, wherein flash heating with said at least one laser includes:
providing a second laser having a beam tuned to a different particular frequency than said beam of said first laser, said different particular frequency is associated with a second material of said film.

12. The method of claim 1, wherein:
said step of depositing said one or more layers is performed in a first chamber; and
said step of flash heating is performed in a second chamber.

13. The method of claim 1, wherein said step of depositing and said step of flash heating are performed in a first chamber, said method further comprising:
moving a flash heat source into said first chamber in order to perform said step of flash heating; and
moving said flash heat source out of said chamber to perform said step of depositing.

14. The method of claim 1, wherein:
said second precursor includes oxygen radicals;
said step of introducing a second precursor includes:
generating a high-density mixed plasma from a radical generating feed gas and a krypton feed gas in a plasma chamber, said high-density mixed plasma forming oxygen radicals from said radical generating feed gas and krypton ions from said krypton feed gas, and
exposing said substrate to said radicals and krypton ions to deposit said film.

15. The method of claim 1, wherein:
said substrate is a silicon wafer.

16. The method of claim 1, wherein:
said substrate is a metal wafer.

17. The method of claim 1, wherein:
said film includes at least one of an oxide, a nitride, an oxynitride, and a metal.

18. The method of claim 1, wherein:
said substrate is in a chamber during each of said deposition cycles;
each of said deposition cycles further includes purging said chamber after introducing said first precursor and purging said chamber after introducing said second precursor.

19. A method of depositing a film, comprising:
depositing one or more layers of said film onto a substrate during a number of deposition cycles, wherein each of said deposition cycles includes introducing a first precursor to said substrate and introducing a second precursor to said substrate; and
flash heating a surface of said film after a predetermined number of said deposition cycles to release contaminants from said film, said predetermined number of said deposition cycles is less than 25.

20. A method of depositing a film, comprising:
depositing one or more layers of said film onto a substrate during a number of deposition cycles, wherein each of said deposition cycles includes introducing a first precursor to said substrate and introducing a second precursor to said substrate; and
flash heating a surface of said film after each deposition cycle to release contaminants from said film.

21. A method of manufacturing a non-volatile storage device, comprising:
depositing a first dielectric region onto a substrate during a number of atomic layer deposition cycles;
flash heating a surface of said first dielectric region after a predetermined number of said atomic layer deposition cycles to release contaminants from said first dielectric region, said flash heating includes raising a temperature of a surface of said first dielectric region without substantially raising a temperature of a bulk of said substrate;
providing a floating gate substantially above said first dielectric region;
providing a second dielectric region substantially above said floating gate; and
providing a control gate substantially above said second dielectric region, wherein charge is transferred between said floating gate and said control gate via said second dielectric region to program said non-volatile storage device.

22. The method of claim 21, wherein:
said predetermined number of said atomic layer deposition cycles is less than 25.

23. The method of claim 21, wherein:
said predetermined number of said atomic layer deposition cycles is one.

24. The method of claim 21, wherein:
said step of providing a floating gate includes at least one of depositing said floating gate and growing said floating gate.

25. The method of claim 21, wherein:
said step of providing a second dielectric region includes at least one of depositing said second dielectric region and growing said second dielectric region.

26. The method of claim 21, wherein:
said step of providing a control gate includes at least one of depositing said control gate and growing said control gate.

27. The method of claim 21, further comprising:
growing at least one interfacial layer between said first dielectric region and said substrate while depositing said first dielectric region, said growing includes exposing said substrate to said radicals.

28. The method of claim 21, wherein:
said first dielectric region has a high dielectric constant.
